(19) United States
(12) Patent Application Publication
(10) Pub. No.: US 2011/0291268 A1
(43) Pub. Date: Dec. 1, 2011

(54) Semiconductor wafer structure and multi-chip stack structure

(76) Inventors: David Wei WANG, Hsinchu (TW); An-Hong Liu, Hsinchu (TW); Hsiang-Ming Huang, Hsinchu (TW); Yi-Chang Lee, Hsinchu (TW)

(21) Appl. No.: 12/856,794

(22) Filed: Aug. 16, 2010

(30) Foreign Application Priority Data
Jun. 1, 2010 (TW) 099117503

(51) Int. Cl. H01L 23/498

(52) U.S. Cl. 257/737; 257/E23.068

(57) ABSTRACT

A semiconductor wafer structure comprises a first surface and a second surface opposite to the first surface, a plurality of chip areas formed on the first surface, a plurality of through-silicon holes formed in each of the plurality of chip areas connecting the first surface and the second surface, and a through-silicon-via (TSV) electrode structure formed in each through-silicon hole. Each through-silicon-via electrode structure comprises a dielectric layer formed on the inner wall of the through-silicon hole, a barrier layer formed on the inner wall of the dielectric layer and defining a vacancy therein, a filling metal layer filled into the vacancy, a first end of the filling metal layer being lower than the first surface forming a recess, and a soft metal cap connecting to and overlaying the first end of the filling metal layer, wherein a portion of the soft metal cap is formed in the recess and the soft metal cap protrudes out of the first surface. Hence, the reliability of multi-chip stack package structure can be enhanced with the application of these soft metal caps.

### BACKGROUND OF THE INVENTION

1. Field of the Invention

The present invention relates to a semiconductor wafer or chip with through-silicon-via electrode structures, and more particularly to a multi-chip stack structure with through-silicon-via electrode structures.

2. Description of the Prior Art

As the trend of designing consumer electronic products leans to meet strong demands for light weight, thinness, and slightness, the integrated circuit manufacturing technologies must keep advancing; for example, the line widths of integrated circuits are getting narrower and narrower. In addition to the requirements for smaller volume and lighter weight, lower price is another requirement for 3C electronic products to comply with. Therefore, the manufacturing cost of various integrated circuit dice which play important roles in 3C electronic products is also required to be reduced accordingly.

To reduce the manufacturing cost of integrated circuit dice, some advanced manufacturers have developed three-dimensional multi-chip stack packaging technology. The 3-D multi-chip stack packaging technology employs wafer-level package technology, in which through-silicon-vias (TSVs) are introduced. The through-silicon-vias are developed by forming vertical through holes in semiconductor wafers and filling the through holes with insulating materials and metallic materials. Copper electrodes which are of relatively high hardness are then formed on the through-silicon-vias to provide vertical interconnection between semiconductor wafers/chips to form the 3-D multi-chip stack structures. During the wafer-to-wafer stacking process, destructive deformations and cracks may occur in the 3-D multi-chip stacked structures due to factors such as alignment error between the metal electrodes and CTE mismatch between different materials of silicon, insulating materials and metals. As shown in FIG. 10, the CTE mismatch may induce potential joint breakage and deformations in x-y-z directions, especially along the Z-axis, at the interfaces between the bonded copper electrodes as well as cracks in silicon, leading to reliability issues of the multi-wafer/multi-chip stack structures with further yield losses in the 3-D multi-chip stack package structures and 3C electronic products.

Therefore, in order to increase the reliability of 3-D multi-chip stack structures, provision of through-silicon-via electrode structures which are able to overcome the CTE mismatch issue and thus solve the alignment problems between the metal electrodes are highly requested.

### SUMMARY OF THE INVENTION

In order to minimize the misalignment problem between metal electrodes and the CTE mismatch issue between different materials and thus to enhance the reliability of the multi-chip stack package structures, the objective of the present invention is to provide a semiconductor wafer structure with some kinds of through-silicon-via electrode structures.

According to the above objective, the present invention first provides a semiconductor wafer structure, which has a first surface and a second surface opposite to the first surface, a plurality chip areas formed on the first surface, a plurality of through-silicon holes formed in each of the plurality of chip areas, wherein the plurality of through-silicon holes connect the first surface and the second surface of the semiconductor wafer, and a through-silicon-via electrode structure formed in each of the plurality of through-silicon holes. The through-silicon-via electrode structure comprises a dielectric layer formed on an inner wall of each of the through-silicon holes, a barrier layer formed on an inner wall of the dielectric layer and defining a vacancy therein, a filling metal layer filled into the vacancy and having a first end and an opposite second end, wherein the first end is lower than the first surface forming a recess therein and the second end is near the second surface, and a first soft metal cap connected to and overlaying the first end of the filling metal layer, wherein a portion of the first soft metal cap is formed in the recess and the first soft metal cap protrudes out of the first surface.

The present invention then provides another semiconductor wafer structure, which has a first surface and a second surface opposite to the first surface, a plurality of chip areas formed on the first surface, a plurality of through-silicon holes formed in each of the plurality of chip areas, wherein the plurality of through-silicon holes connect the first surface and the second surface of the semiconductor wafer, and a through-silicon-via electrode structure formed in each of the plurality of through-silicon holes. The through-silicon-via electrode structure comprises a dielectric layer formed on an inner wall of each of the through-silicon holes, a barrier layer formed on an inner wall of the dielectric layer and defining a vacancy therein, a filling metal layer filled into the vacancy and having a first end and an opposite second end, wherein the first end is lower than the first surface forming a first recess therein and the second end is lower than the second surface forming a second recess therein, a first soft metal cap connected to and overlaying the first end of the filling metal layer, wherein a portion of the first soft metal cap is formed in the first recess and the first soft metal cap protrudes out of the first surface, and a second soft metal cap connected to and overlaying the second end of the filling metal layer, wherein a portion of the second soft metal cap is formed in the second recess and the second soft metal cap protrudes out of the second surface.

The present invention also provides a multi-chip stack structure which is formed by vertically stacking a plurality of semiconductor chips. Each of the plurality of semiconductor chips has a first surface, a second surface opposite to the first surface, a plurality of through-silicon holes formed therein and connecting the first surface and the second surface of the semiconductor chip, and a through-silicon-via electrode structure formed in each of the plurality of through-silicon holes. The through-silicon-via electrode structure comprises a dielectric layer formed on an inner wall of each of the through-silicon holes, a barrier layer formed on an inner wall of the dielectric layer and defining a vacancy therein, a filling metal layer filled in the vacancy and having a first end and an opposite second end, wherein the first end is lower than the first surface forming a recess therein and the second end is flush with the second surface, and a first soft metal cap connected to and overlaying the first end of the filling metal layer, wherein a portion of the first metal cap is formed in the recess and the first soft metal cap protrudes out of the first surface. Thus, the first soft metal caps of one of the plurality of semiconductor chips are electrically connected to the second ends of the filling metal layer of another one of the plurality of semiconductor chips to form the multi-chip stack structure.

In one embodiment of the multi-chip stack structure of the present invention, the through-silicon-via electrode structure further comprises a second soft metal cap, which is connected to and overlaying the second end of the filling metal layer and protrudes out of the second surface. Thus, the first soft metal caps of one of the plurality of semiconductor chips are electrically connected to the second soft metal caps of another one of the plurality of semiconductor chips to form the multi-chip stack structure.

The present invention also provides a multi-chip stack structure formed by vertically stacking a plurality of semiconductor chips, wherein each of the plurality of semiconductor chips has a first surface, a second surface opposite to the first surface, a plurality of through-silicon holes formed therein and connecting the first surface and the second surface of the semiconductor chips, and a through-silicon-via electrode structure formed in each of the plurality of through-silicon holes. The through-silicon-via electrode structure comprises a dielectric layer formed on an inner wall of each of the through-silicon holes, a barrier layer formed on an inner wall of the dielectric layer and defining a vacancy therein, a filling metal layer filled into the vacancy and having a first end and an opposite second end, wherein the first end is lower than the first surface forming a first recess therein and the second end is lower than the second surface forming a second recess therein, a first soft metal cap connected to and overlaying the first end of the filling metal layer, wherein a portion of the first soft metal cap is formed in the first recess and the first soft metal cap protrudes out of the first surface, and a second soft metal cap connected to and overlaying the second end of the filling metal layer, wherein a portion of the second soft metal cap is formed in the second recess and the second soft metal cap protrudes out of the second surface. Thus, the first soft metal caps of one of the plurality of semiconductor chips are electrically connected to the second soft metal caps of another one of the plurality of semiconductor chips to form the multi-chip stack structure.

The present invention further provides a semiconductor wafer structure, which has a first surface and a second surface opposite to the first surface, a plurality of chip areas formed on the first surface, a plurality of through-silicon holes formed in each of the plurality of chip areas and connecting the first surface and the second surface, and a through-silicon-via electrode structure formed in each of the plurality of through-silicon holes. The through-silicon-via electrode structure comprises a dielectric layer formed on an inner wall of each of the through-silicon holes, a barrier layer formed on an inner wall of the dielectric layer and defining a vacancy therein, a ringlike filling metal layer formed on an inner wall of the barrier layer and partially filling the vacancy to form a hollow region therein, wherein a first end of the ring-like filling metal layer is near the first surface and a second end opposite to the first end is near the second surface, and a first soft metal cap formed on the first end of the ringlike filling metal layer and protruding out of the first surface.

In one embodiment of the above semiconductor wafer structure of the present invention, the first soft metal cap is a ringlike cap which has at least one through hole therein, and the at least one through hole coincides with the hollow region.

In another embodiment of the above semiconductor wafer structure of the present invention, the through-silicon-via electrode structure further comprises a polymer insulating layer filling the hollow region.

In still another embodiment of the above semiconductor wafer structure of the present invention, the through-silicon-via electrode structure further comprises a second soft metal cap which is formed on the second end of the ringlike filling metal layer and protrudes out of the second surface.

The present invention further provides a multi-chip stack structure formed by vertically stacking a plurality of semiconductor chips. Each of the plurality of semiconductor chips has a first surface and a second surface opposite to the first surface, a plurality of through-silicon holes formed therein and connecting the first surface and the second surface, and a through-silicon-via electrode structure formed in each of the through-silicon holes. The through-silicon-via electrode structure comprises a dielectric layer formed on an inner wall of each of the through-silicon holes, a barrier layer formed on an inner wall of the dielectric layer and defining a vacancy therein, a ringlike filling metal layer formed on an inner wall of the barrier layer and partially filling the vacancy to form a hollow region therein, wherein a first end of the ringlike filling metal layer is near the first surface and an opposite second end is near the second surface, and a first soft metal cap formed on the first end of the ringlike filling metal layer and protruding out of the first surface. Thus, the plurality of first soft metal caps of one of the plurality of semiconductor chips are electrically connected to the second ends of the ringlike filling metal layers of another one of the plurality of semiconductor chips to form the multi-chip stack structure.

In one embodiment of the above multi-chip stack structure of the present invention, the first soft metal cap is a ringlike cap which has at least one through hole therein, and the at least one through hole coincides with the hollow region.

In another embodiment of the above multi-chip stack structure of the present invention, the through-silicon-via electrode structure further comprises a polymer insulating layer filling the hollow region.

In still another embodiment of the above multi-chip stack structure of the present invention, the through-silicon-via electrode structure further comprises a second soft metal cap which is formed on the second end of the ringlike filling metal layer and protrudes out of the second surface.

### BRIEF DESCRIPTION OF THE DRAWINGS

FIG. 1A to FIG. 1E show the partial cross-sectional views of the process of a first embodiment for forming a semiconductor wafer structure with through-silicon-via electrode structures, according to the present invention;

FIG. 1F to FIG. 1I show the partial cross-sectional views of the process of another embodiment for forming a semiconductor wafer structure with through-silicon-via electrode structures, according to the present invention;

FIG. 1J shows the partial cross-sectional view of an embodiment of a semiconductor wafer structure with through-silicon-via electrode structures including UBM layers, according to the present invention;

FIG. 2A to FIG. 2D show the partial cross-sectional views of an embodiment of the semiconductor wafer structure with the through-silicon-via electrode structures, according to the present invention;

FIG. 3A to FIG. 3D show the partial cross-sectional views of the process of another embodiment for forming the semiconductor wafer with the through-silicon-via electrode structures, according to the present invention;

FIG. 3E shows the partial cross-sectional view of an embodiment of a semiconductor wafer structure with through-silicon-via electrode structures including UBM layers, according to the present invention;

FIG. 4A to FIG. 4D show the partial cross-sectional views of an embodiment of the multi-chip stack structures, according to the present invention;

FIG. 5A to FIG. 5G show the partial cross-sectional views of an embodiment of the semiconductor wafer structure with through-silicon-via electrode structures having ringlike filling metal layers, according to the present invention;

FIG. 5H shows the partial cross-sectional view of an embodiment of the semiconductor wafer structure with through-silicon-via electrode structures having ringlike filling metal layers and UBM layers, according to the present invention;

FIG. 6A to FIG. 6D show the partial cross-sectional views of the embodiment of the semiconductor wafer structure with the through-silicon-via electrode structures having the ringlike filling metal layers as shown in FIG. 5A to FIG. 5G, according to the present invention;

FIG. 7A to FIG. 7C show the partial cross-sectional views of another embodiment of the semiconductor wafer structure with the through-silicon-via electrode structures having the ringlike filling metal layers, according to the present invention;

FIG. 7D shows the partial cross-sectional view of an embodiment of the semiconductor wafer structure with through-silicon-via electrode structures having ringlike filling metal layers and UBM layers, according to the present invention;

FIG. 8A to FIG. 8C show the partial cross-sectional views of an embodiment of the multi-chip stack structures with the ringlike filling metal layers, according to the present invention;

FIG. 9 shows the cross-sectional view of an embodiment of the multi-chip stack structure, according to the present invention; and

FIG. 10 shows the cross-sectional view of a conventional structure, according to prior art.

### DESCRIPTION OF THE PREFERRED EMBODIMENT

The objective of the present invention is to provide a semiconductor wafer with through-silicon-via electrode structures to minimize mismatch of coefficient of thermal expansion between different materials and to further increase the reliability of chip stack packages. The present invention is to be described more fully hereinafter with reference to the accompanying drawings, in which preferred embodiments are shown. Apparently, methods for stacking semiconductor chips are not limited in the present invention, especially methods well-known to those skilled in the art; on the other hand, well-known technologies not directly related to this invention such as the formation of integrated circuit chips and the process of thinning the wafers would not be described in detail in the following to prevent from unnecessary interpretations of or limits to the present invention. However, this invention can be embodied in many different forms and extensively applied in other embodiments and should not be construed as limited to the preferred embodiments set forth herein. Moreover, it should be appreciated that dimensional relationships among individual elements in the attached drawings are depicted in an exaggerative way for ease of understanding.

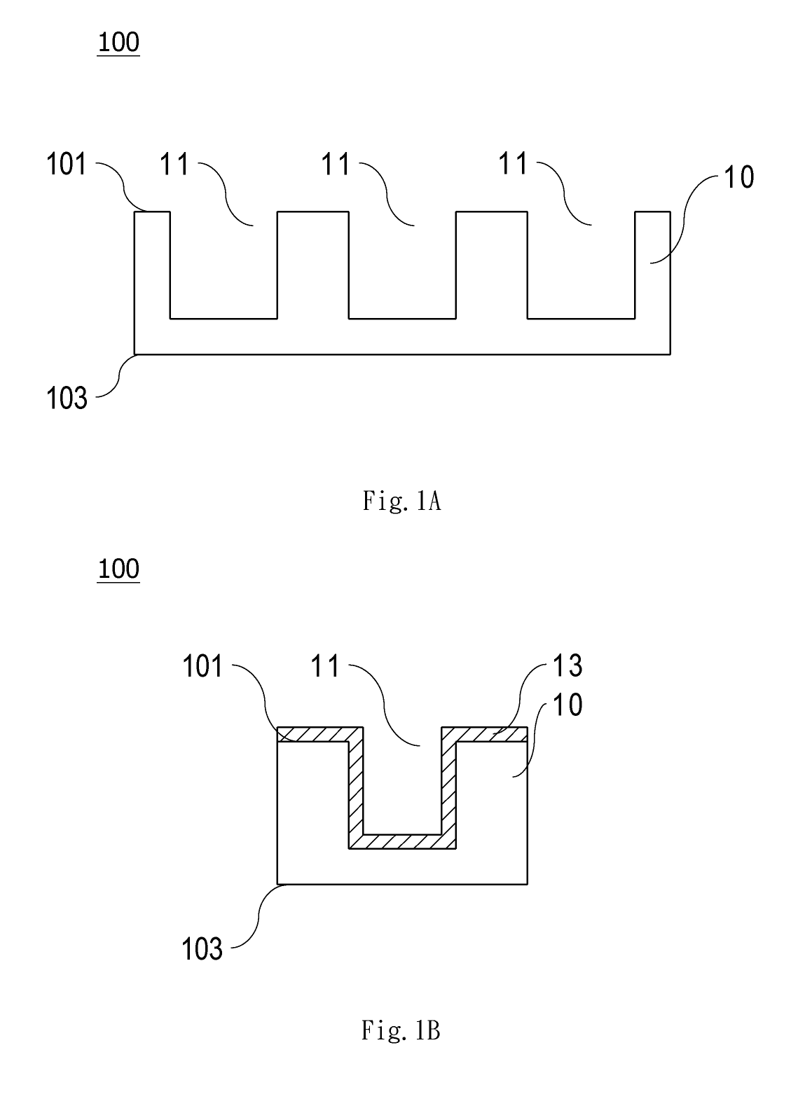

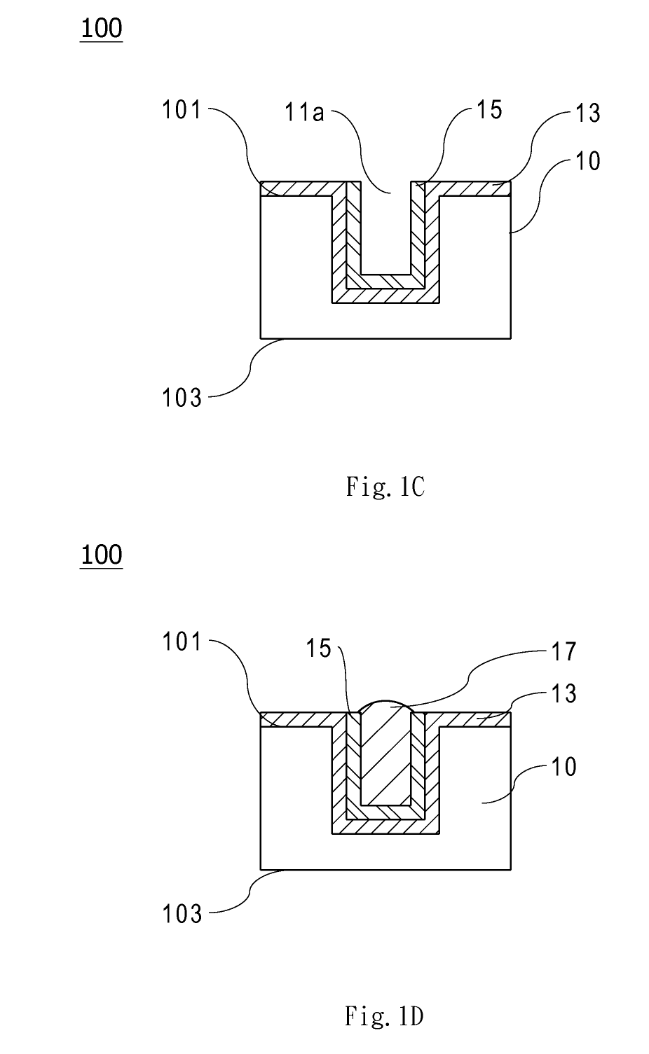

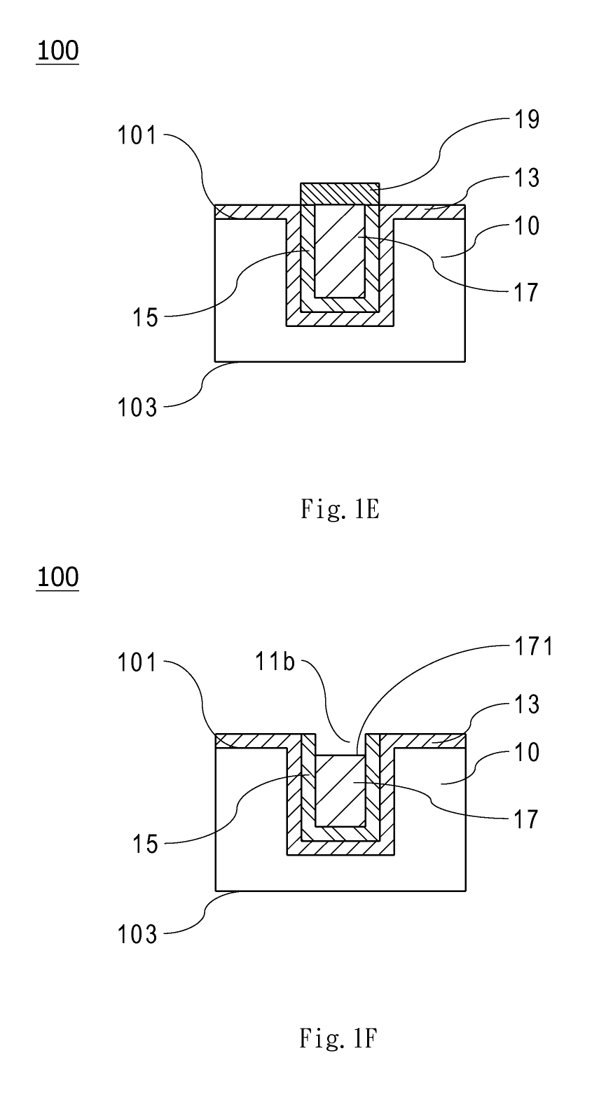

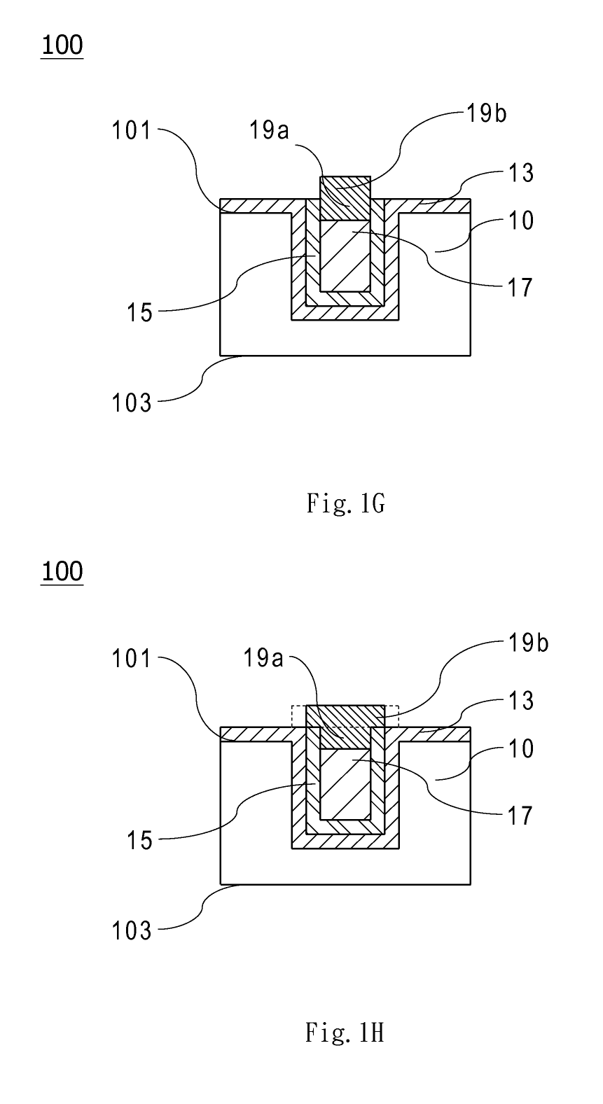

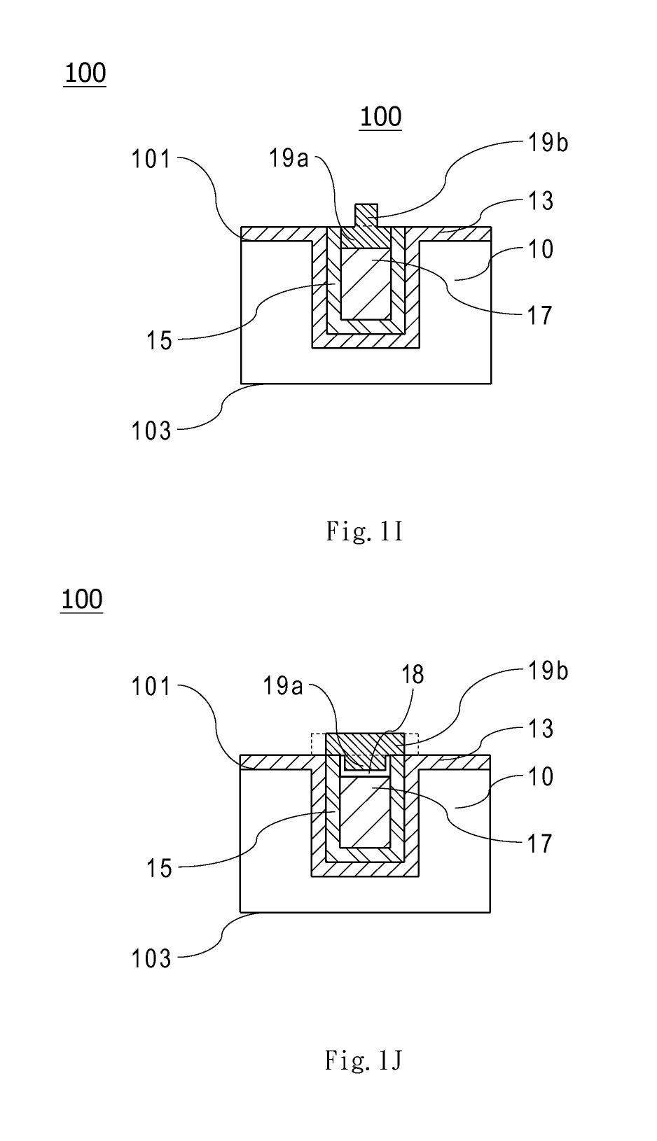

FIG. 1A to FIG. 1I, which are the partial cross-sectional views of one embodiment of a semiconductor wafer structure of the present invention with through-silicon-via electrode structures, illustrate the process for forming the through-silicon-via electrode structures in a semiconductor wafer. First, a semiconductor wafer 10 is provided, which has a first surface (active surface) 101 and a second surface 103 opposite to the first surface 101. A plurality of chip areas 100 are formed on the first surface 101 of the semiconductor wafer 10, and a plurality of pads (not shown) are disposed on each of the plurality of chip areas 100 as the terminals of the semiconductor chip for electrically connecting the semiconductor chip to external devices. Then, a plurality of recesses 11 are formed in each of the plurality of chip areas 100 corresponding to the plurality of pads. The recesses 11 are vertically formed from the first surface 101 to the second surface 103 without penetrating the second surface 103, as shown in FIG. 1A. The recesses 11 can be formed by laser drilling, dry etching, or wet etching. The width of the recesses 11 is between about 1 um and 50 um, preferably between 10 um and 20 um. In the present invention, the semiconductor wafer 10 can be a memory, logic, controller, ASIC, CPU, DSP, MEMS, Photovoltaic or RF wafer, which is not limited in the present invention.

For the following figures, only one recess 11 (or through-silicon-via electrode structure further formed in the recess) is shown in each figure to simplify the drawings for illustrating the present invention more clearly. Referring to FIG. 1B, a dielectric layer 13 is formed on the inner wall and the bottom of each of the recesses 11 in the plurality of chip areas 100. The dielectric layer 13 can be an oxide layer formed by thermal process. In a preferred embodiment, the dielectric layer 13 is formed on the inner wall and bottom of the recess 11 by plasma-enhanced chemical vapor deposition (PECVD). The purpose of using PECVD to form the dielectric layer 13 is to avoid high temperatures during the processes. In addition, the dielectric layer 13 can also be made of polymer material, for example, polyimide, which is filled into the recess 11 with unneeded part removed by laser drilling up to a desired thickness. Furthermore, the material of the dielectric layer 13 can be selected from low-k materials, such as Black diamond, coral, Black Diamond II, Aurora 2.7, Aurora ULK, SILK, HSQ, MSQ, porous SiO₂, porous Carbon-doped SiO₂, and methods for forming the dielectric layer 13 can be chemical vapor deposition (CVD) or spin-on coating. In addition, the material of dielectric layer 13 can be selected from the group consisting of: SiO₂, BCB (Benzocyclobutene), SiCO, SiCN, SiN and SiC. The thickness of the dielectric layer 13 is between about 500 Å and 10,000 Å, preferably between 2,000 Å and 5,000 Å, and the most preferred thickness is about 2500 Å. Yet, the thickness of the dielectric layer 13 covering the first surface 101 of the semiconductor wafer 10 is relatively thin compared to the thickness of the semiconductor wafer 10 and can be ignored; thus, the first surface 101 covered with the dielectric layer 13 can still be deemed as the first surface 101 of the semiconductor wafer 10.

Next, referring to FIG. 1C, after the dielectric layer 13 of a specific thickness is formed on the inner wall and the bottom of the recess 11, a barrier layer 15 is then formed on the inner wall and on the bottom of the dielectric layer 13. The thickness of the barrier layer 15 is smaller than that of the dielectric layer 13. For example, the thickness of the barrier layer 15 is between 1,000 Å and 5,000 Å, preferably about 2,000 Å. The material of the barrier layer 15 is selected from the group consisting of: Tantalum (Ta), TaN, TaC, Titanium (Ti), TiN, TiW, TiCu, W×N and the combination thereof. Furthermore, the method for forming the barrier layer 15 can be sputtering, for example, sputtering Ti or Ta onto the inner wall and the bottom of the dielectric layer 13, and then sputtering copper on the Ti or Ta layer to form a barrier layer 15. In addition, when the aspect ratio (AR) of the recess 11 is relatively large, such as 10:1, chemical grafting or electroplated grafting can be used to form the barrier layer 15. Since the thicknesses of the dielectric layer 13 and the barrier layer 15 are small, the recess 11 is not fully filled by the dielectric layer 13 and the barrier layer 15 so that a vacancy 11a is defined therein.

Then, as shown in FIG. 1D, after the barrier layer 15 is formed, a metal is filled into the vacancy 11a, by plating process for instance, to form a filling metal layer 17. Alternatively, the filling metal layer 17 can also be formed by electroless plating, via filling, or conductive inserts. The material of the filling metal layer 17 can be selected from the group consisting of: poly-silicon, copper (Cu), tungsten (W), nickel (Ni), aluminum (Al) and the metal alloy of the combination thereof. In the present invention, copper (Cu) is the preferred material of the filling metal layer 17. When the filling metal layer 17 fully fills the vacancy 11a, a protruding end of the filling metal layer 17 would be formed near the opening of the vacancy 11a. Then, a soft metal cap 19 is formed on the protruding end of the filling metal layer 17 for connecting to and overlaying the protruding end of the filling metal layer 17. Certainly, sizes of the soft metal caps 19 can be adjusted according to different requirements such that the soft metal cap 19 further overlays the barrier layer 15 and even a portion of the dielectric layer 13, forming a metal electrode structure.

In order to minimize deformations of the bonded metal electrodes due to CTE mismatch between different materials, soft metals are employed to form the metal electrode structures. The soft metal cap 19 can be selected from electroplated bump, electroless bump, stud bump or conductive polymer bump. The material of the soft metal cap p 19 can be selected from the group consisting of: gold, nickel/gold, nickel/palladium/gold, tin solder, lead-free solder, and conductive polymer material. In the present invention, gold (Au) or nickel/gold is the preferred material(s) of the soft metal cap 19 where nickel is an optional interlayer disposed between the gold metal cap and the copper filling metal layer. Soft metals implemented in the metal electrode structures with the characteristics of low modulus of elasticity and good ductility can provide better compliancy which can compensate vertical and horizontal deformations which may occur at the interface between two bonded metal electrodes due to the CTE mismatch between different materials during vertical stacking of multiple wafers or chips. In addition, roughness issue between the metal electrodes and coplanarity issue between the metal electrodes and the substrate can also be overcome. Thus, the reliability of processes and products of the multi-wafer or multi-chip stack structures can be enhanced.

In order to increase the reliability of the multi-chip vertical stack structures, the present invention provides another soft metal electrode structure. Referring to FIG. 1F, the filling metal layer 17 which is formed by electroplating method, for instance, can be terminated before the filling metal layer 17 fully fills the vacancy 11a by means of controlling the deposition time so that a first end 171 of the filling metal layer 17 is formed at a level lower than the first surface 101 of the semiconductor wafer 10, forming a first recess 11b in the vacancy 11a. Then, a soft metal is applied to form a soft metal cap 19 on the first end 171 of the filling metal layer 17. The soft metal cap 19 includes a soft metal cap 19a formed in the first recess 11b and a soft metal cap 19b protruding from the first surface 101, in which the soft metal cap 19a is connected to and overlays the first end 171 of the filling metal layer 17, and the soft metal cap 19b serves as the contact for external connection. The soft metal cap 19 can be formed by integrally forming the soft metal caps 19a and 19b or separately forming the soft metal cap 19a and the soft metal cap 19b in sequence. In addition, size of the soft metal cap 19b can vary simply by adjusting the size of opening of the photoresist layer disposed on the first surface 101. For example, the soft metal cap 19b with a horizontal dimension identical to that of the soft metal cap 19a, as shown in FIG. 1G. In addition, the soft metal cap 19b can further overlay the barrier layer 15 and even a portion of the dielectric layer 13 to form a soft metal cap 19b with a horizontal dimension larger than that of the soft metal cap 19a, as shown in FIG. 1H, where the dotted line shows the extent of the soft metal cap 19b to be extended. Moreover, the soft metal cap 19b can be formed covering only a portion of the soft metal cap 19a to form a stepped soft metal cap 19, as shown in FIG. 1I. Forms of the soft metal cap 19b are not limited in the present invention. Similarly, the soft metal cap 19 can be selected from electroplated bump, electroless bump, stud bump or conductive polymer bump, and the material of the soft metal cap 19 can be selected from the group consisting of: gold, nickel/gold, nickel/palladium/gold, tin solder, lead-free solder, and conductive polymer material. In the present invention, gold (Au) or nickel/gold is the preferred material(s) of the soft metal cap 19 where nickel is an optional interlayer disposed between the gold metal cap and the copper filling metal layer.

Furthermore, the present invention further discloses another embodiment of through-silicon-via electrode structures, as shown in FIG. 1J, in which a UBM layer (Under Bump Metallurgy Layer) 18 is formed between the first end 171 of the filling metal layer 17 and the soft metal cap 19a of the aforementioned embodiment. For example, as shown in FIG. 1F, after the filling metal layer 17 is filled in the vacancy 11a, a UBM layer 18 with a thickness between 100 and 2000 Å is first formed on the first end 171 of the filling metal layer 17, and the soft metal cap 19a/19b is then formed on the UBM layer 18. In this embodiment, the method for forming the UBM layer 18 can be selected from the following: evaporation, sputtering, electroplating, or electroless plating. The material of the UBM layer 18 can be selected from the group consisting of: Ti, Ti/Cu, Ti/W, Ti/W/Au, Ti/Cu/Cu, Ti/Cu/Ni, Ti/W/Cu, Ti/W/Cu/Ni, Ti/W/Ni, Ni/V, Ni, and Ni/Pd. Moreover, the UBM layer 18 can be formed only on the first end 171 of the filling metal layer 17, or further on the inner wall of the barrier layer 15 in the first recess 11b (as shown in FIG. 1J), or further formed on the first surface 101 of the semiconductor wafer 10 so as to overlay the barrier layer 15 and even a portion of the dielectric layer 13. Apparently, forming a UBM layer 18 between the first end 171 of the filling metal layer 17 and the soft metal cap 19a can also be applied to the structure as shown in FIG. 1D similarly, where detailed description is omitted herein. In this embodiment, the UBM layer 18 can provide good adhesion between the filling metal layer 17 and the soft metal cap 19a, and serve as a diffusion barrier, wetting, and protective layer.

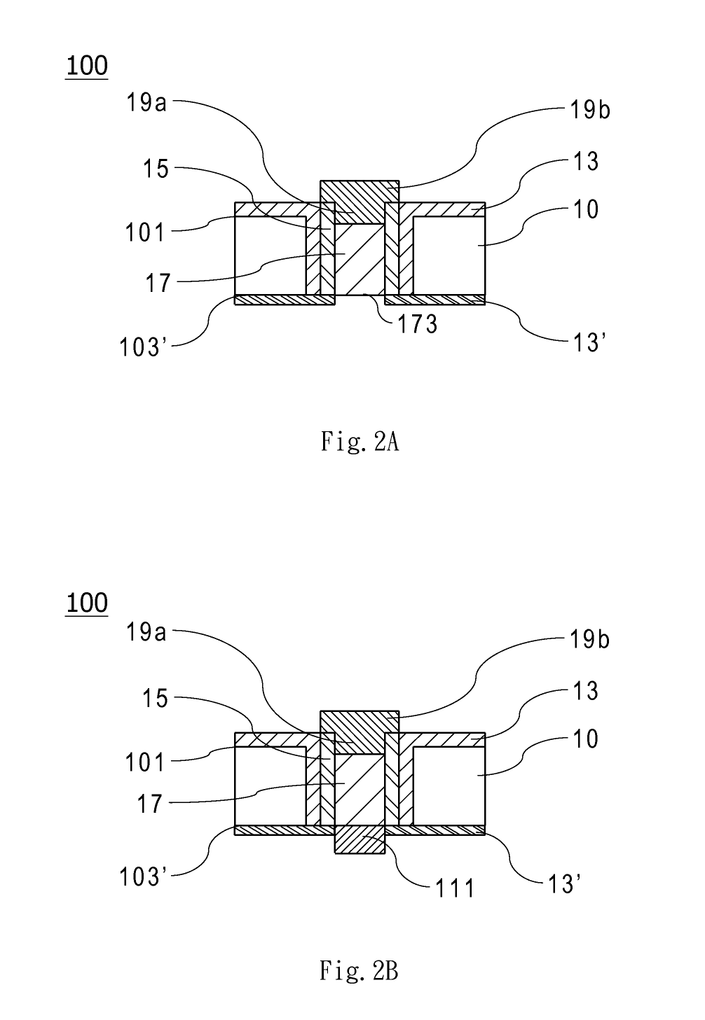

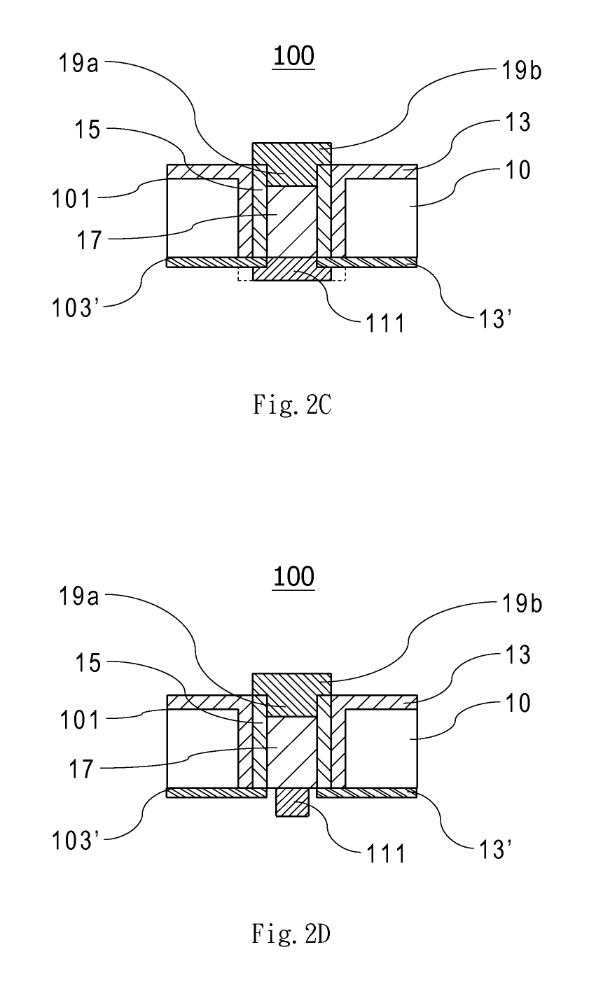

Next, please refer to FIG. 2A to FIG. 2D, which are the partial cross-sectional views of the process for forming the semiconductor wafer structure with through-silicon-via electrode structures of an embodiment of the present invention. It is emphasized that the soft metal cap 19 formed on the first end 171 of the filling metal layer 17 is exemplarily shown as that in FIG. 1H in the subsequent description. Certainly, the structure of the soft metal cap 19 can also be like the structure as shown in FIG. 1G or FIG. 1I.

After the soft metal cap 19 is formed on the first end 171 of the filling metal layer 17, wafer thinning process is then performed on the second surface 103 of the semiconductor wafer 10, for instance, by means of conventional lapping with lapping wheels incorporated with chemical mechanical polishing (CMP) or plasma etching. Thus, the semiconductor wafer 10 is thinned until a second end 173 of the filling metal layer 17 is exposed so that a through-silicon-via (TSV) electrode structure is formed, as shown in FIG. 2A. Obviously, the surface of the second end 173 of the filling metal layer 17 is flush with the lapped second surface 103′ of the semiconductor wafer 10.

Next, a soft metal cap 111 is formed on the exposed second end 173 of the filling metal layer 17 for connecting to and overlaying the second end 173 of the filling metal layer 17 as a metal electrode. Obviously, both ends of the through-silicon hole are configured with soft metal caps, which are electrically connected by the filling metal layer 17. In addition, a thin dielectric layer 13′ can be optionally deposited or coated on the lapped second surface 103′ of the semiconductor wafer 10 before the soft metal cap 111 is formed. The dielectric layer 13′ exposes the second end 173 of the filling metal layer 17, and the soft metal cap 111 is then formed on the exposed second end 173 of the filling metal layer 17, as shown in FIG. 2B. Formation of the dielectric layer 13′ is to prevent occurrence of leakage current or short circuit. The thickness of the dielectric layer 13′ covering the lapped second surface 103′ is relatively thin compared to the thickness of the semiconductor wafer 10 so that it can be ignored; thus, the lapped second surface 103′ covered with the dielectric layer 13′ is still referred to with the same reference number 103′ in the following description.

Moreover, shapes and dimensions of the soft metal cap 111 formed on the second end 173 of the filling metal layer 17 can be like the structure shown in FIG. 2B, FIG. 2C, or FIG. 2D. The various structures in the above-mentioned figures can be obtained by adjusting the size of opening of the photoresist layer used to form the soft metal cap 111 and controlling the electroplating time. For example, as shown in FIG. 2B, a soft metal cap 111 with a horizontal dimension identical to that of the filling metal layer 17 is formed. As shown in FIG. 2C, opening of the photoresist layer is widened to form a soft metal cap 111 with a horizontal dimension larger than that of the filling metal layer 17. Thus, the soft metal cap 111 also overlays the barrier layer 15 and even a portion of the dielectric layer 13′, the dotted line in the figure showing the extent of the soft metal cap 111 to be extended. As shown in FIG. 2D, opening of the photoresist layer is narrowed so as to form a soft metal cap 111 with a horizontal dimension smaller than that of the filling metal layer 17. Similarly, the soft metal cap 111 can be selected from electroplated bump, electroless bump, stud bump or conductive polymer bump, and the material of the soft metal cap 111 can be selected from the group consisting of: gold, nickel/gold, nickel/palladium/gold, tin solder, lead-free solder, and conductive polymer material. In the present invention, gold (Au) or nickel/gold is the preferred material(s) of the soft metal cap 111 where nickel is an optional interlayer disposed between the gold metal cap and the copper filling metal layer.

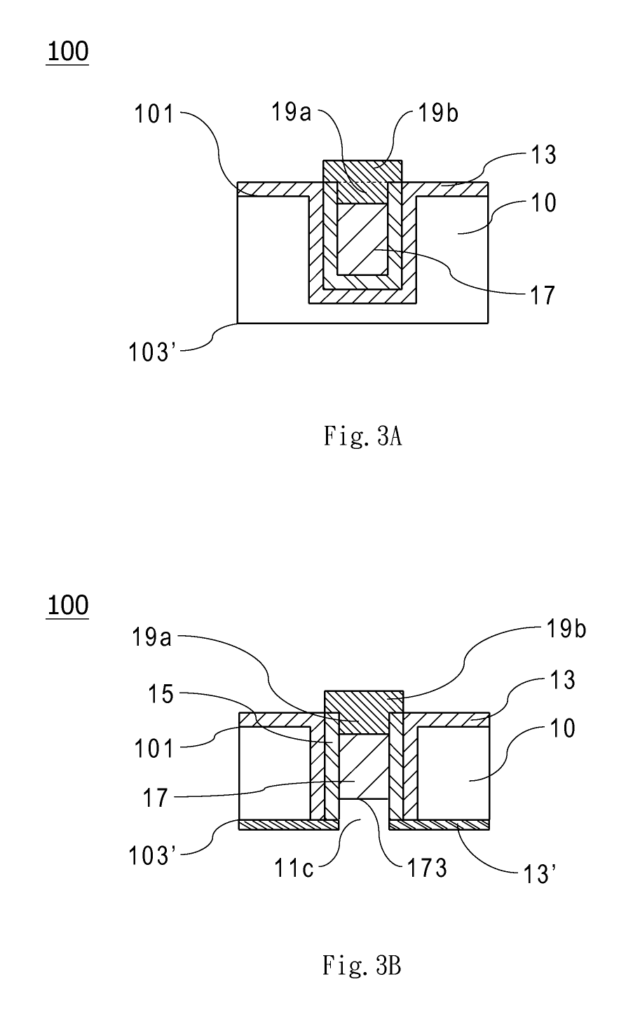

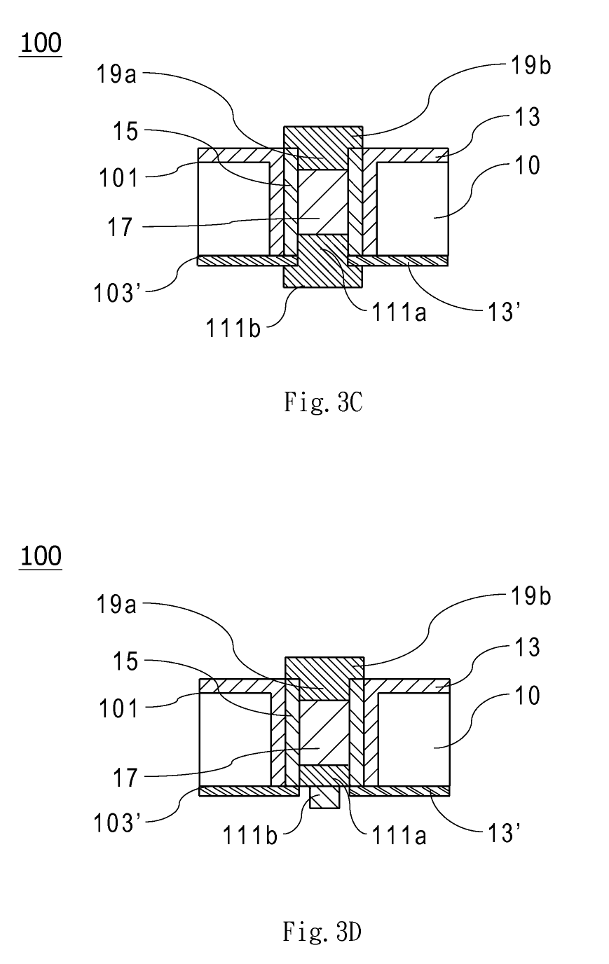

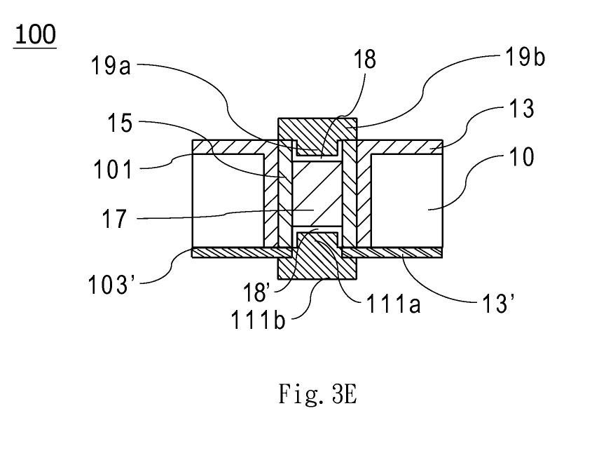

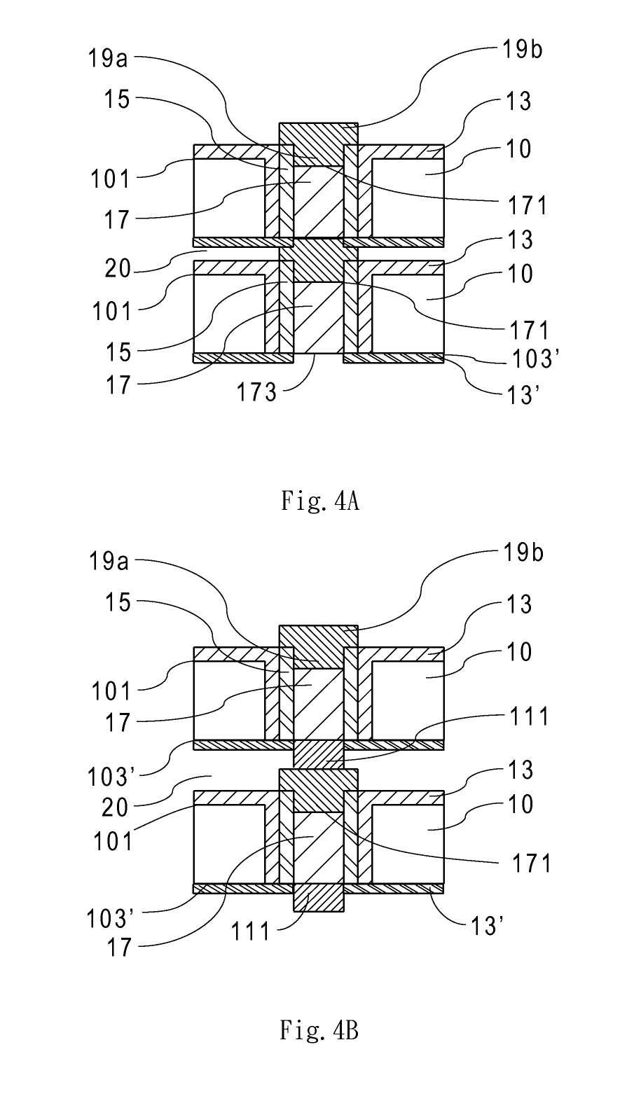

The present invention further provides another embodiment. Please refer to FIG. 3A to FIG. 3D, which are the partial cross-sectional views of the process for forming the semiconductor wafer structure with through-silicon-via electrode structures of another embodiment of the present invention. First, wafer thinning process is performed on the second surface 103 of the semiconductor wafer 10. The difference between this embodiment and the embodiment shown in FIG. 2A is that the thinning process is stopped at a predetermined thickness without exposing the second end 173 of the filling metal layer 17. Then, the lapped second surface 103′ of the semiconductor wafer 10, the dielectric layer 13, and the barrier layer 15 at the location corresponding to each of the through-silicon holes are removed, for instance, by an etching process until the second end 173 of the filling metal layer 17 is exposed. Thus, the second end 173 of the filling metal layer 17 is lower than the lapped second surface 103′ of the semiconductor wafer 10 forming a second recess 11c, as shown in FIG. 3B.

Furthermore, another method for forming the structure in FIG. 3B is illustrated in the following. The second surface 103 of the semiconductor wafer 10 is thinned until the second end 173 of the filling metal layer 17 is exposed as shown in FIG. 2A. Then, the exposed second end 173 of the filling metal layer 17 is further removed to a predetermined depth by etching process, for instance, to form the second recess 11c. Thus, the second end 173 of the filling metal layer 17 is lower than the lapped second surface 103′ of the semiconductor wafer 10 as shown in FIG. 3B. Similarly, a thin dielectric layer 13′ can be deposited or coated on the lapped second surface 103′ of the semiconductor wafer 10 but exposes the second end 173 of the filling metal layer 17. Next, a soft metal material is filled into the second recess 11c to form a soft metal cap 111 on the second end 173 of the filling metal layer 17 by, for instance, electroplating process. The soft metal cap 111 includes a soft metal cap 111a formed in the second recess 11c and a soft metal cap 111b protruding from the second surface 103′, as shown in FIG. 3C. The soft metal cap 111a is connected to and overlays the second end 173 of the filling metal layer 17, and the soft metal cap 111b serves as the contact for external connection. In the present embodiment, similar to the soft metal caps 19a and 19b, the soft metal cap 111 can be formed by integrally forming the soft metal caps 111a and 111b or separately forming the soft metal cap 111a and the soft metal cap 111b in sequence. Size of the soft metal cap 111b can vary simply by adjusting the size of opening of the photoresist layer disposed on the second surface 103′. For example, the soft metal cap 111b can further overlay the barrier layer 15 and even a portion of the dielectric layer 13′, forming a soft metal cap 111b with a horizontal dimension larger than that of the soft metal cap 111a, as shown in FIG. 3C. Also, the soft metal cap 111b can be formed only on a portion of the soft metal cap 111a as shown in FIG. 3D. Shapes and dimensions of the soft metal cap 111b are not limited in the present invention. Similarly, the soft metal cap 111 can be selected from electroplated bump, electroless bump, stud bump or conductive polymer bump, and the material of the soft metal cap 111 can be selected from the group consisting of: gold, nickel/gold, nickel/palladium/gold, tin solder, lead-free solder, and conductive polymer material. In the present invention, gold (Au) or nickel/gold is the preferred material(s) of the soft metal cap 111 where nickel is an optional interlayer disposed between the gold metal cap and the copper filling metal layer. Obviously, both ends of the through-silicon hole are now configured with soft metal caps, which are electrically connected by the filling metal layer 17, forming a through-silicon-via electrode structure.

Moreover, the present invention further discloses another embodiment of through-silicon-via electrode structures, as shown in FIG. 3E, in which a UBM layer 18 is formed between the first end 171 of the filling metal layer 17 and the soft metal cap 19a of the aforementioned embodiment, and a UBM layer 18′ is also formed between the second end 173 of the filling metal layer 17 and the soft metal cap 111a. The method for forming the UBM layers 18 and 18′ and the thickness, material, structure and function of the UBM layers are the same as that shown in FIG. 1J; thus, detailed description is omitted herein.

In the above-mentioned embodiments, soft metals implemented in the metal electrode structures with the characteristics of low modulus of elasticity and good ductility can provide better compliancy which can compensate vertical and horizontal deformations which may occur at the interface between two bonded metal electrodes due to the CTE mismatch between different materials during vertical stacking of multiple wafers or chips. In addition, roughness issue between the metal electrodes and coplanarity issue between the metal electrodes and the substrate can also be overcome. Thus, reliability of processes and products of the multi-wafer or multi-chip stack structures can be enhanced.

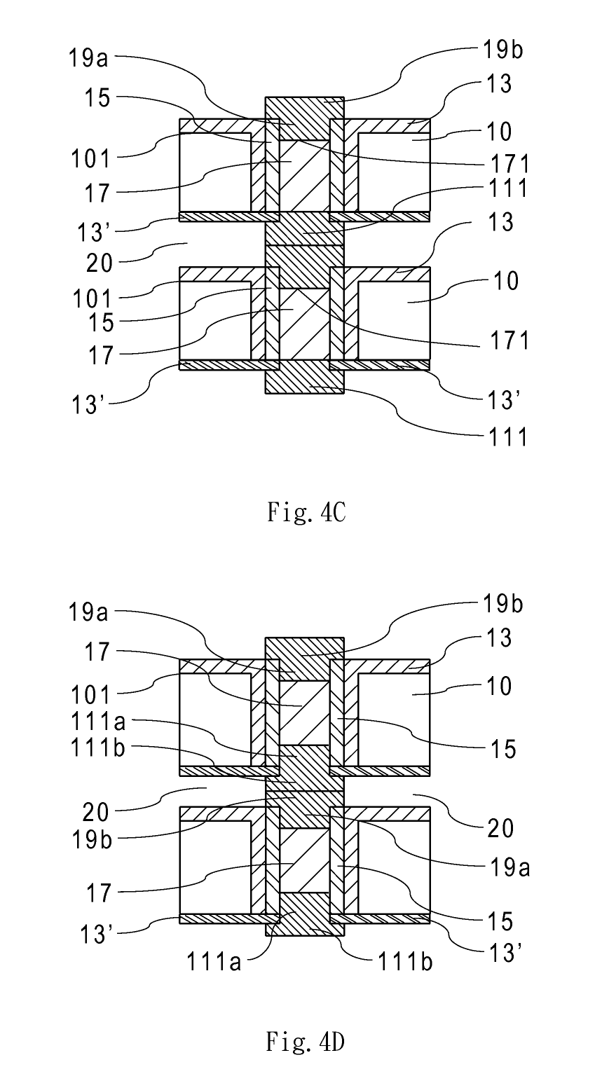

Now, through-silicon-via electrode structures with soft metal caps formed on one or both ends of each of the through-silicon holes are formed in each of the plurality of chip areas 100 corresponding to a plurality of pads disposed on the semiconductor wafer 10, wherein the soft metal caps serve as the contacts for external electrical connection. Then, a chip stacking process can be performed. After an alignment process is performed, a semiconductor chip with a plurality of through-silicon-via electrode structures is vertically stacked on another semiconductor chip with a plurality of through-silicon-via electrode structures and bonded together by thermo-compressing process, thermo-sonic bonding process, or ultrasonic bonding process so that the second ends of the filling metal layers or the soft metal caps protruding out of the second surface of an upper chip are connected with the soft metal caps protruding out of the first surface of a lower chip, respectively. In the present invention, ultrasonic bonding is the most preferred bonding method. Accordingly, the foregoing two-chip stack structure can further be vertically bonded to more semiconductor chips similarly configured with a plurality of through-silicon-via electrode structures to form a three-dimensional multi-chip stack structure. As the method for stacking multiple semiconductor chips in the present embodiment is similar to the method in the conventional art and is thus not described in detail in the following; those who are skilled in the art are supposed to be able to complete multi-chip stacking by using semiconductor chips with a plurality of through-silicon-via electrode structures provided by the present embodiment. Moreover, the multi-chip stack structures can be constituted as one of the following: vertically stacking a plurality of semiconductor chips with through-silicon-via electrode structures as shown in FIG. 2A to form a multi-chip stack structure as shown in FIG. 4A, vertically stacking a plurality of semiconductor chips with through-silicon-via electrode structures as shown in FIG. 2B to form a multi-chip stack structure as shown in FIG. 4B, vertically stacking a plurality of semiconductor chips with through-silicon-via electrode structures as shown in FIG. 2C to form a multi-chip stack structure as shown in FIG. 4C, or vertically stacking a plurality of semiconductor chips with through-silicon-via electrode structures as shown in FIG. 3C to form a multi-chip stack structure as shown in FIG. 4D. It is emphasized that the above-mentioned constitutions of the multi-chip stack structure are only some embodiments of the present invention. Any combinations of semiconductor chips with the through-silicon-via electrode structures as disclosed in FIG. 2A, FIG. 2B, FIG. 2C, FIG. 2D, FIG. 3B, FIG. 3C and FIG. 3D can be selected for fabricating the multi-chip stack structures. Hence, the present invention is not limited to the foregoing embodiments shown in FIG. 4A to FIG. 4D. In addition, the semiconductor chips can be memory, logic, controller, ASIC, CPU, DSP, MEMS, Photovoltaic or RF devices, which are not limited in the present invention.

Furthermore, it should be illustrated that process for forming the multi-chip stack structure can be performed by stacking a plurality of semiconductor wafers 10 to form a wafer-to-wafer stack structure, followed by a wafer saw process which is performed to cut along the scribe lines between the plurality of chip areas on the semiconductor wafers 10 of the stacked wafer structure to form a plurality of multi-chip stack structures. Alternatively, the semiconductor wafer 10 can first be sawed into a plurality of individual semiconductor chips. Then, the plurality of individual semiconductor chips are stacked to one another to form a chip-to-chip multi-chip stack structure. Also, the plurality of individual semiconductor chips can be bonded to the chip areas on a semiconductor wafer 10 correspondingly to form a chip-to-wafer stack structure, followed by a wafer saw process along the scribe lines between the plurality of chip areas on the semiconductor wafer 10 to form a plurality of multi-chip stack structures. The number of semiconductor chips to be stacked is not limited in this invention.

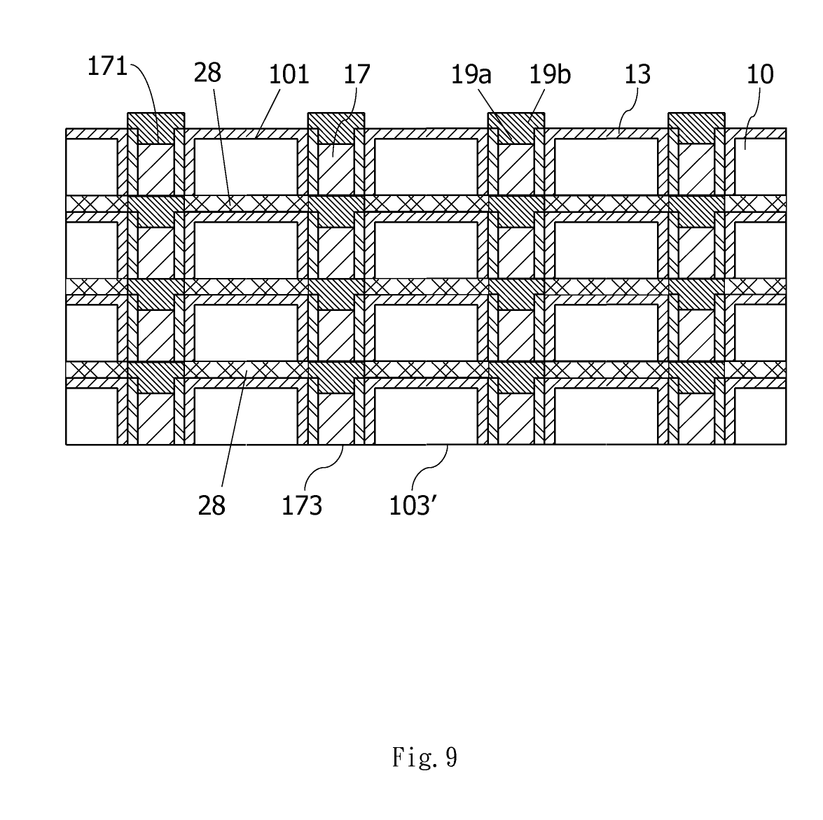

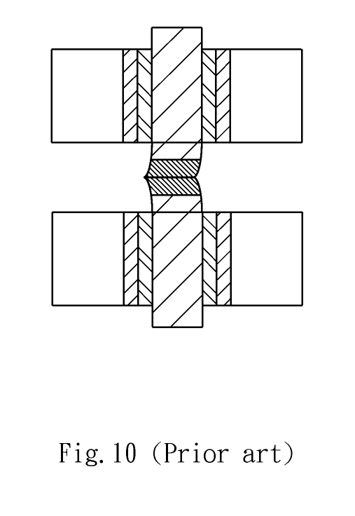

Meanwhile, a sealing application step can optionally be performed during the multi-chip stacking process. A sealing material can be applied on the first surface 101 of the semiconductor wafer 10 or chip by dispensing, printing, or spin-coating method. When the semiconductor wafers or chips are bonded together, the sealing material is cured to form a sealing layer 28 in the gap 20 between each two adjacent semiconductor wafers or chips of the multi-chip stack structures, as shown in FIG. 9. Thus, the sealing layer 28 can facilitate the multi-chip stack structure to be securely bonded and protect the electrical interconnects. The material of the sealing layer 28 is selected from the group consisting of: non-conductive paste (NCP), non-conductive film (NCF), anisotropic conductive paste (ACP), anisotropic conductive film (ACF), underfill, non-flow underfill, B-stage resin, molding compound, and film-over-wire (FOW). In the present invention, non-conductive paste (NCP) is the most preferred sealing material.

Furthermore, the sealing process also can be optionally performed after the multi-chip stack structure is fabricated. The sealing material is filled into the gap 20 between each two adjacent semiconductor wafers or chips of the multi-chip stack structures to form a sealing layer 28, as shown in FIG. 9.

As shown in FIG. 4A, the present invention provides a first embodiment of multi-chip stack structure that is formed by vertically stacking a plurality of semiconductor chips with through-silicon-via electrode structures of FIG. 2A. Please also refer to FIGS. 1B, 1C and 1F. Each of the plurality of semiconductor chips has a first surface 101, a second surface 103′ opposite to the first surface 101 and a plurality of through-silicon holes 11 formed therein. The plurality of through-silicon holes 11 connect the first surface 101 and the second surface 103′. A through-silicon-via electrode structure is formed in each of the plurality of through-silicon holes 11, and the through-silicon-via electrode structure comprises a dielectric layer 13 formed on an inner wall of the through-silicon hole 11, a barrier layer 15 formed on an inner wall of the dielectric layer 13 and defining a vacancy 11a therein, a filling metal layer 17 filled into the vacancy 11a and having a first end 171 and a second end 173 opposite to the first end 171, wherein the first end 171 is lower than the first surface 101 forming a recess 11b therein and the second end 173 is flush with the second surface 103′, and a soft metal cap 19a/19b connected to and overlaying the first end 171 of the filling metal layer 17, the soft metal cap 19a being formed in the recess 11b and the soft metal cap 19b protruding from the first surface 101. In this embodiment, the multi-chip stack structure is formed by connecting a plurality of soft metal caps 19a/19b of one of the plurality of semiconductor chips to the second ends 173 of the plurality of filling metal layers 17 of another semiconductor chip.

Next, as shown in FIG. 4B, the present invention provides a second embodiment of multi-chip stack structure which is formed by vertically stacking a plurality of semiconductor chips with through-silicon-via electrode structures of FIG. 2B. In this embodiment, each of the structures on the first surface 101 of the semiconductor chip in FIG. 2B is identical to that in FIG. 2A; the difference is that a soft metal cap 111 is further formed on the second end 173 of each of the plurality of filling metal layers 17 near the lapped second surface 103′ of the semiconductor chip in FIG. 2A. In this embodiment, the horizontal dimension of the soft metal cap 111 is identical to that of the filling metal layer 17. Thus, the multi-chip stack structure is formed by connecting the plurality of soft metal caps 19a/19b of one of the plurality of semiconductor chips to the plurality of soft metal caps 111 of another semiconductor chip.

Next, as shown in FIG. 4C, the present invention provides a third embodiment of multi-chip stack structure which is formed by vertically stacking a plurality of semiconductor chips with through-silicon-via electrode structures of FIG. 2C. In this embodiment, similar to the semiconductor chip in FIG. 2B, soft metal caps 111 are formed on the second ends 173 of the plurality of filling metal layers 17, but the horizontal dimension of the soft metal cap 111 is larger than that of the filling metal layer 17 so that the soft metal cap 111 overlays the barrier layer 15 and even a portion of the dielectric layer 13′. Thus, the multi-chip stack structure is formed by connecting the plurality of soft metal caps 19a/19b of one of the plurality of semiconductor chips to the plurality of soft metal caps 111 of another semiconductor chip.

Moreover, as shown in FIG. 4D, the present invention provides a fourth embodiment of multi-chip stack structure which is formed by vertically stacking a plurality of semiconductor chips with through-silicon-via electrode structures of FIG. 3C. In this embodiment, each of the structures on the first surface 101 of the semiconductor chip in FIG. 3C is identical to that in FIG. 2A, FIG. 2B and FIG. 2C; the difference is that the second end 173 of the filling metal layers 17 of the semiconductor chip in FIG. 3C is lower than the lapped second surface 103′ forming a second recess (11c as shown in FIG. 3B) therein. The soft metal cap 111a/111b is partially filled into the second recess with the soft metal cap 111b protruding from the second surface 103′ and being larger than the soft metal cap 111a that is filled in the second recess in horizontal dimension. In this embodiment, the multi-chip stack structure is formed by connecting the soft metal caps 19a/19b of one of the plurality of semiconductor chips to the soft metal caps 111a/111b of another semiconductor chip.

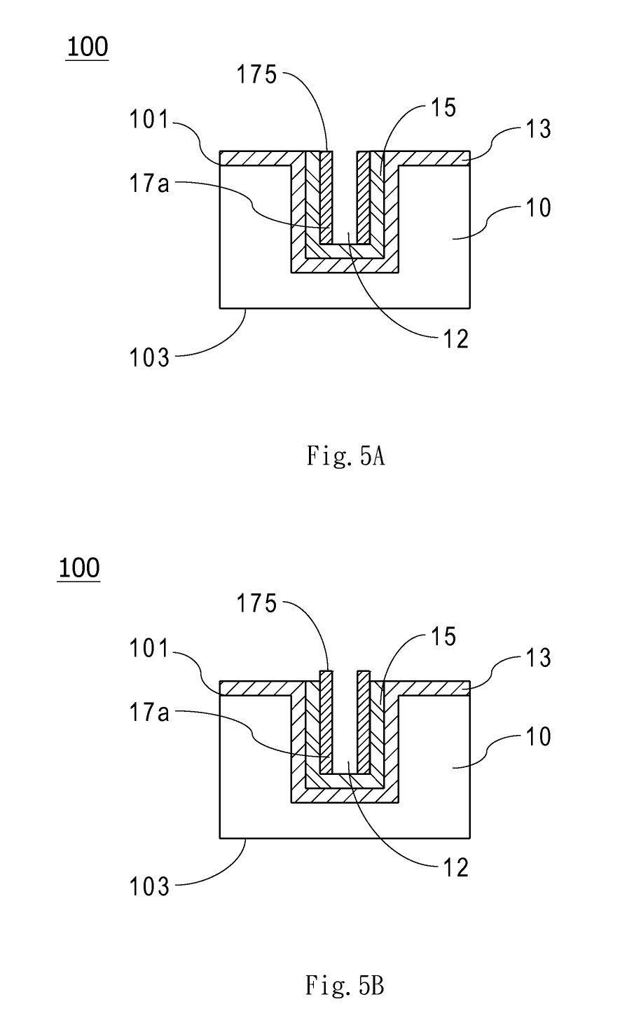

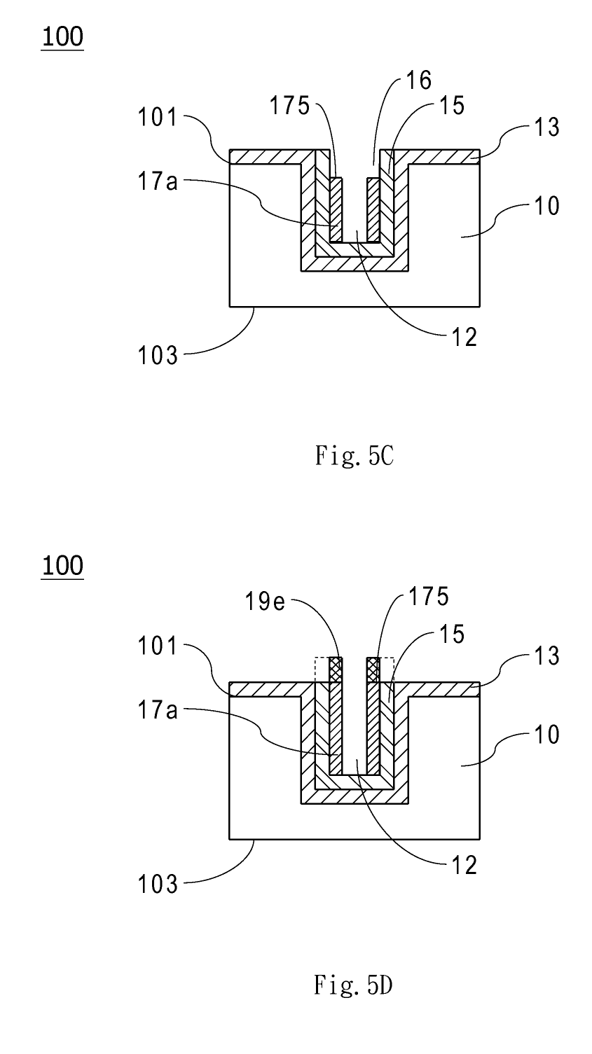

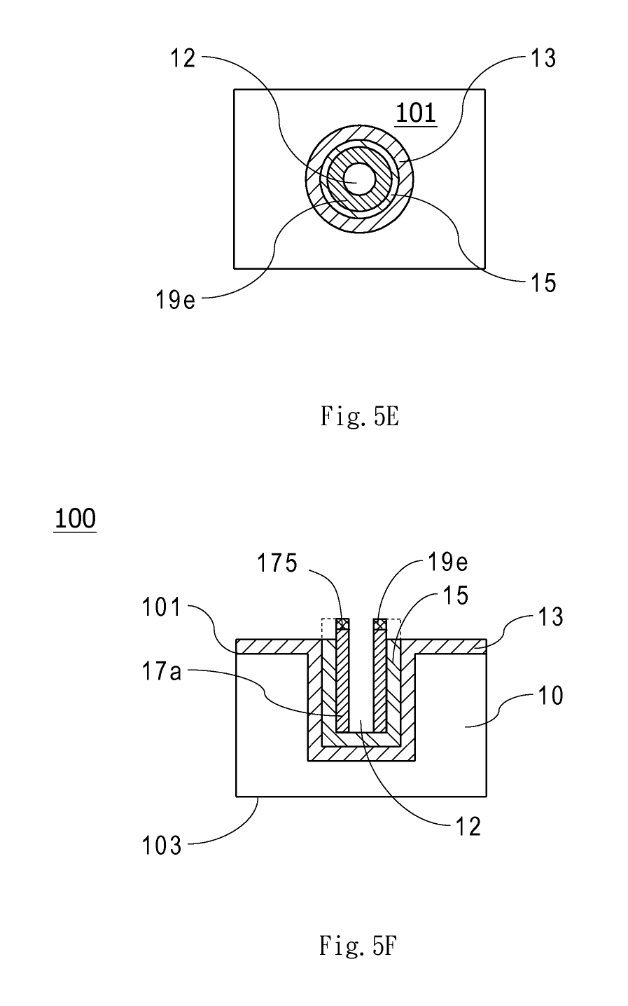

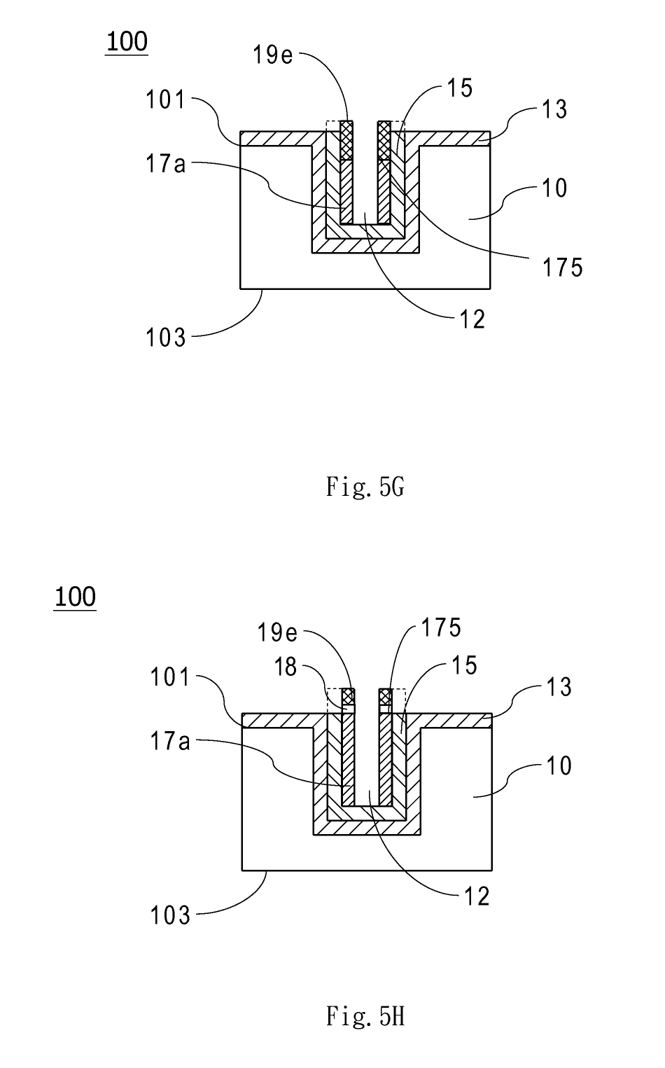

The present invention now provides another embodiment of the semiconductor wafer structure with through-silicon-via electrode structures, as shown in FIG. 5A to FIG. 5E. Please also refer to FIG. 1A to FIG. 1C. A semiconductor wafer 10 has a first surface 101 and a second surface 103 opposite to the first surface 101. A plurality of chip areas 100 are formed on the first surface 101 of the semiconductor wafer 10. A plurality of pads (not shown) are disposed on each of the plurality of chip areas 100 to be as the terminals of the semiconductor chip for electrically connecting the semiconductor chip to the external device. Then, a plurality of recesses 11 are formed in each of the plurality of chip areas 100 corresponding to the plurality of pads. The recesses 11 are vertically formed from the first surface 101 to the second surface 103 but do not penetrate the second surface 103, as previously shown in FIG. 1A. Then, a dielectric layer 13 is formed on the inner wall of the recess 11. Next, a barrier layer 15 is formed on the inner wall of the dielectric layer 13. Formations and materials of the dielectric layer 13 and the barrier layer 15 are the same as the above-mentioned. Since the thicknesses of the dielectric layer 13 and the barrier layer 15 are small, the recess 11 is not fully filled by the dielectric layer 13 and the barrier layer 15 so that a vacancy 11a is defined therein as described above for FIG. 1C.

Then, a metal material is filled into the vacancy 11a, for instance, by a plating process. The metal material can be selected from the group consisting of: poly-silicon, copper (Cu), tungsten (W), nickel (Ni), aluminum (Al), and the metal alloy of the combination thereof. In the present invention, copper (Cu) is the preferred material of the filling metal. Thus, a ringlike filling metal layer 17a is formed on the inner wall of the barrier layer 15, which partially fills the vacancy 11a to form a hollow region 12 thereon, as shown in FIG. 5A. The first end 175 of the ringlike filling metal layer 17a is flush with the first surface 101. Yet, the structure of the ringlike filling metal layer 17a can vary by, for example, controlling the process time to obtain a first end 175 of the ringlike filling metal layer 17a higher than the first surface 101 as shown in FIG. 5B, or a first end 175 of the ringlike filling metal layer 17a lower than the first surface 101 for forming a recess 16 as shown in FIG. 5C.

Then, a soft metal material is applied to form a soft metal cap 19e on the first end 175 of the ringlike filling metal layer 17a to be a metal electrode structure. First, as shown in FIG. 5D, the soft metal cap 19e is formed on the first end 175 of the ringlike filling metal layer 17a which is flush with the first surface 101, in which the soft metal cap 19e is a ringlike cap as shown in FIG. 5E. The ringlike soft metal cap 19e has a through hole that coincides with the hollow region 12. Therefore, excessive gases or liquids in the hollow region 12 can be discharged during processes to prevent voids from forming in the ringlike filling metal layer 17a. Sizes of the soft metal cap 19e can be adjusted according to the different requirements. For example, as shown in FIG. 5D, the soft metal cap 19e can be with a horizontal dimension identical to that of the ringlike filling metal layer 17a to overlay the ringlike filling metal layer 17a, or with a horizontal dimension larger than that of the ringlike filling metal layer 17a to further overlay the barrier layer 15 and even a portion of the dielectric layer 13 as the dotted line shown in FIG. 5D. Furthermore, the size of the through hole in the ring-like soft metal cap 19e can be identical to, larger than or smaller than that of the hollow region 12 as long as the through hole is sufficient for excessive gases or liquids in the hollow region 12 to discharge. Furthermore, the soft metal cap 19e can be selected from electroplated bump, electroless bump or conductive polymer bump, and the material of the soft metal cap 19e can be selected from the group consisting of: gold, nickel/gold, nickel/palladium/gold, tin solder, lead-free solder, and conductive polymer material. In the present invention, gold (Au) or nickel/gold is the preferred material(s) of the soft metal cap 19e where nickel is an optional interlayer disposed between the gold metal cap and the copper ringlike filling metal layer. However, the material of the soft metal cap is not to be limited.

Moreover, the soft metal cap 19e can also be formed on a first end 175 of the ringlike filling metal layer 17a which is higher than the first surface 101 (as shown in FIG. 5B). Similar to the aforementioned, the soft metal cap 19e can be with a horizontal dimension identical to the ringlike filling metal layer 17a to overlay the ringlike filling metal layer 17a as shown in FIG. 5F, or with a horizontal dimension larger than that of the ringlike filling metal layer 17a to further overlay the barrier layer 15 and even a portion of the dielectric layer 13 as the dotted line shown in FIG. 5F. In addition, the size of the through hole of the ringlike soft metal cap 19e can be adjusted according to the requirements; thus, it is not to be limited herein.

Furthermore, in this embodiment, a soft metal cap 19e can also be formed on a first end 175 of the ringlike filling metal layer 17a which is lower than the first surface 101 (as shown in FIG. 5C). Obviously, a portion of the soft metal cap 19e is formed in the recess 16 and the remaining portion of the soft metal cap 19e protrudes from the first surface 101 to be a metal electrode structure. Similarly, the protruding portion of soft metal cap 19e can be with a horizontal dimension identical to that of the ring-like filling metal layer 17a, as shown in FIG. 5G, or with a horizontal dimension larger than that of the ringlike filling metal layer 17a to further overlay the barrier layer 15 and even a portion of the dielectric layer 13 as the dotted line shown in FIG. 5G. Also, the size of the through hole of the ringlike soft metal cap 19e can be adjusted according to the requirements; thus, it is not to be limited herein.

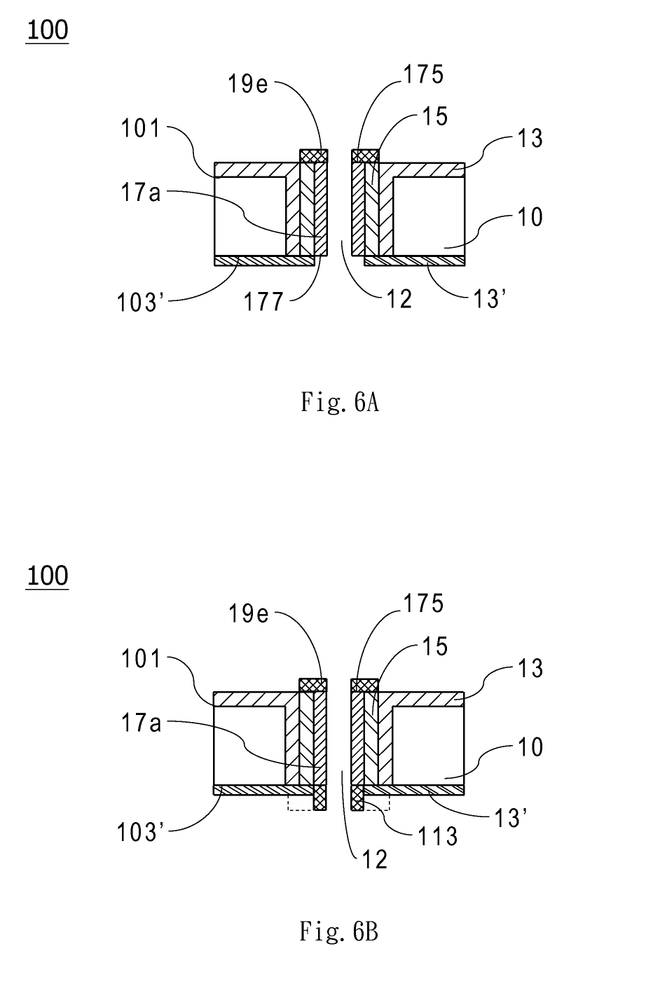

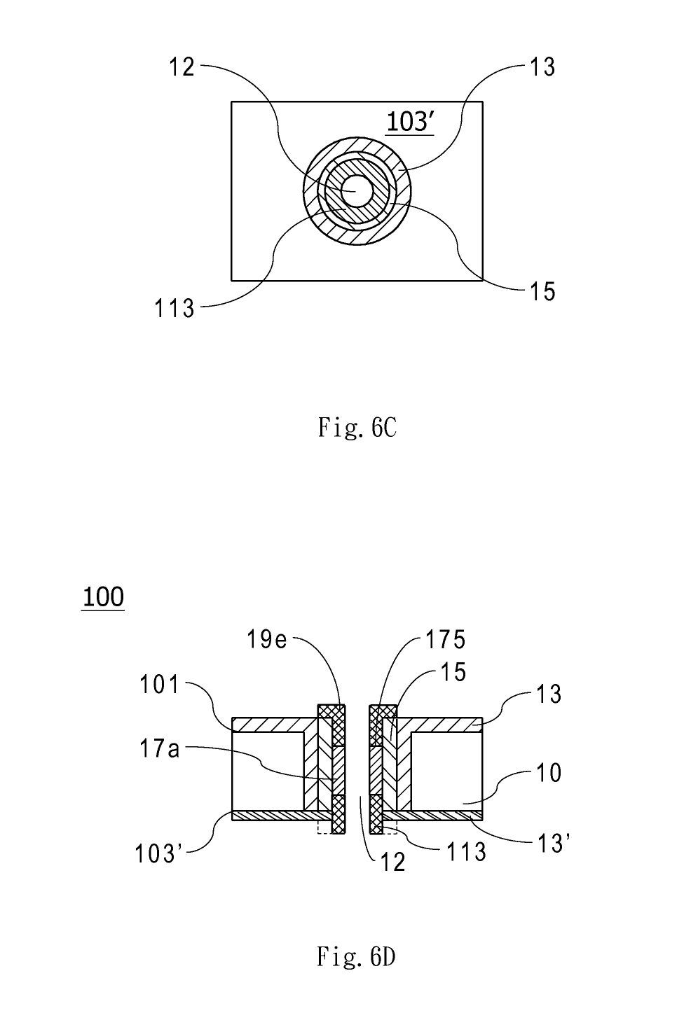

The present invention further discloses an embodiment of through-silicon-via electrode structures, as shown in FIG. 5H, in which a UBM layer (Under Bump Metallurgy Layer) 18 is formed between the first end 175 of the ringlike filling metal layer 17a and the soft metal cap 19e of the aforementioned embodiment. For example, after the ringlike filling metal layer 17a is formed in the vacancy 12, as shown in FIG. 5A, a UBM layer 18 with a thickness between 100 and 2000 Å is first formed on the first end 175 of the ringlike filling metal layer 17a. In this embodiment, the UBM layer 18 can be formed by one of the following methods: evaporation, sputtering, electroplating, or electroless plating. The UBM layer 18 may be formed on the first end 175 and the inner wall of the ringlike filling metal layer 17a and further formed on the first surface 101 of the semiconductor wafer 10, overlaying the barrier layer 15 and even a portion of the dielectric layer 13. The soft metal cap 19e is then formed on the UBM layer 18. The UBM layer 18 formed on the inner wall of the ringlike filling metal layer 17a and on the first surface 101 of the semiconductor wafer 10 can be removed optionally by, for example, wet etching method so that only the part of UBM layer 18 interposed between the first end 175 of the ringlike filling metal layer 17a and the soft metal cap 19e remains, as shown in FIG. 5H. Apparently, forming a UBM layer between the ringlike filling metal layer 17a and the soft metal cap can also be applied to the structures as shown in FIGS. 5F, 5G, 6A, 6B, and 6D similarly, where a UBM layer can also be formed between the second end 177 of the ringlike filling metal layer 17a and the soft metal cap 113 for the structures as shown in FIGS. 6A, 6B and 6D. The material and the function of the UBM layer 18 are the same as that in the embodiment shown in FIG. 1J; thus, detailed description is omitted herein

It is emphasized that the soft metal cap 19e formed on the first end 175 of the ringlike filling metal layer 17a is exemplarily shown as that in FIG. 5D in the following illustrations. Certainly, the soft metal cap 19e can also be like the structures as shown in FIG. 5F or in FIG. 5G. After the ringlike electrode structure of the soft metal cap 19e is formed on the first surface 101 of the semiconductor wafer 10, wafer thinning process is then performed on the second surface 103 of the semiconductor wafer 10, for example, by means of conventional lapping with lapping wheels incorporated with chemical mechanical polishing (CMP) or plasma etching. Thus, the semiconductor wafer 10 is thinned until the second end 177 of the ringlike filling metal layer 17a is exposed so that a through-silicon-via (TSV) electrode structure is formed. Obviously, the second end 177 of the ringlike filling metal layer 17a is flush with the lapped second surface 103′ of the semiconductor wafer 10, as shown in FIG. 6A. Then, a soft metal cap 113 is formed on the exposed second end 177 of the ringlike filling metal layer 17a to be a metal electrode, as shown in FIG. 6B. Optionally, a thin dielectric layer 13′ can be deposited or coated on the lapped second surface 103′ of the semiconductor wafer 10 before the soft metal cap 113 is formed, wherein the dielectric layer 13′ exposes the second end 177 of the ringlike filling metal layer 17a. However, since the thickness of the dielectric layer 13′ is relatively small and can be ignored, the lapped second surface 103′ covered with the dielectric layer 13′ is still referred to with the same reference number 103′ in the following illustrations. The material of the dielectric layer 13′ is the same as the above-mentioned dielectric layer 13; hence, detailed description is omitted herein. Formation of the dielectric layer 13′ is to prevent occurrence of leakage current and electrical short. In this embodiment, the soft metal cap 113 is a ringlike cap and has a through hole that coincides with the hollow region 12, as shown in FIG. 6C. Meanwhile, both ends of the through-silicon hole are configured with soft metal caps, which are electrically connected by the ringlike filling metal layer 17. Similarly, the size of the soft metal cap 113 can be adjusted according to the requirements. As aforementioned, the soft metal cap 113 can be with a horizontal dimension identical to the ringlike filling metal layer 17a to overlay the ringlike filling metal layer 17a, as shown in FIG. 6B, or with a horizontal dimension larger than that of the ringlike filling metal layer 17a to further overlay the barrier layer 15 and even a portion of the dielectric layer 13′ as the dotted line shown in FIG. 6B. In addition, the size of the through hole of the ringlike soft metal cap 113 can be adjusted according to the requirements; thus, it is not to be limited herein. Moreover, the soft metal cap 113 can also be a solid structure as the soft metal cap 111 in FIG. 2. Similar to the soft metal cap 19e, the soft metal cap 113 can be selected from electroplated bump, electroless bump, stud bump or conductive polymer bump, and the material of the soft metal cap 113 can be selected from the group consisting of: gold, nickel/gold, nickel/palladium/gold, tin solder, lead-free solder, and conductive polymer material. In the present invention, gold (Au) or nickel/gold is the preferred material(s) of the soft metal cap 113 where nickel is an optional interlayer disposed between the gold metal cap and the copper ringlike filling metal layer.

Furthermore, the present invention provides another embodiment as shown in FIG. 6D. The difference between this embodiment and the illustration of FIG. 6A is that the thinning process on the second surface 103 of the semiconductor wafer 10 is stopped at a predetermined thickness and without exposing the second end 177 of the ringlike filling metal layer 17a. Then, the lapped second surface 103′ of semiconductor wafer 10, the dielectric layer 13, and the barrier layer 15 at the location corresponding to each of the through-silicon holes are removed, for instance, by an etching process until the second end 177 of the ringlike filling metal layer 17a is exposed. Thus, the second end 177 of the ringlike filling metal layer 17a is lower than the lapped second surface 103′ of the semiconductor wafer 10 forming a recess therein. Similarly, a dielectric layer 13′ can be deposited or coated on the lapped second surface 103′ of the semiconductor wafer 10 but exposes the second end 177 of the ringlike filling metal layer. Next, the soft metal cap 113 is formed on the exposed second end 177 of the ringlike filling metal layer 17a, as shown in FIG. 6D, and a portion of the soft metal cap 113 is formed in the recess and the remaining portion of the soft metal cap 113 protrudes from the lapped second surface 103′ of the semiconductor wafer 10 to be a metal electrode. Similar to the above-mentioned, the protruding portion of the soft metal cap 113 can be with a horizontal dimension identical to that of the ringlike filling metal layer 17a, or with a horizontal dimension larger than that of the ringlike filling metal layer 17a to further overlay the barrier layer 15 and even a portion of the dielectric layer 13′ as the dotted line shown in FIG. 6D. Also, in this embodiment, the soft metal cap 113 is a ringlike cap with a through hole formed therein. The size of the through hole can be adjusted according to the requirements; thus, it is not to be limited herein. Similarly, the soft metal cap 113 also can be a solid structure. In addition, another method for forming the structure as shown in FIG. 6D is described as follows. Wafer thinning process is performed on the second surface 103 of the semiconductor wafer 10 until the second end 177 of the ringlike filling metal layer 17a is exposed. Then, the exposed second end 177 of the ringlike filling metal layer 17a is further removed to a predetermined depth by etching process, for instance, to form the recess, thus the second end 177 of the ringlike filling metal layer 17a is lower than the lapped second surface 103′ of the semiconductor wafer 10. Next, the soft metal cap 113 is formed.

It is emphasized again that soft metals implemented in the metal electrode structures with the characteristics of low modulus of elasticity and good ductility can provide better compliancy which can compensate vertical and horizontal deformations which may occur at the interface between two bonded metal electrodes due to the CTE mismatch between different materials during vertical stacking of multiple wafers or chips. In addition, roughness issue between the metal electrodes and coplanarity issue between the metal electrodes and the substrate can be overcome. Thus, the reliability of processes and products of the multi-wafer or multi-chip stack structures can be enhanced. Especially, as the filling metal layer is a hollow ringlike structure, the compliancy at the connection interfaces of the metal electrodes would be improved to prevent deformation in horizontal direction from occurring during the multi-wafer or multi-chip stacking processes. When additional stress is exerted on the dielectric layer, damage to the dielectric layer which may cause leakage current or electrical short can be prevented. Thus, the reliability of the multi-wafer or multi-chip stack structures can further be enhanced.

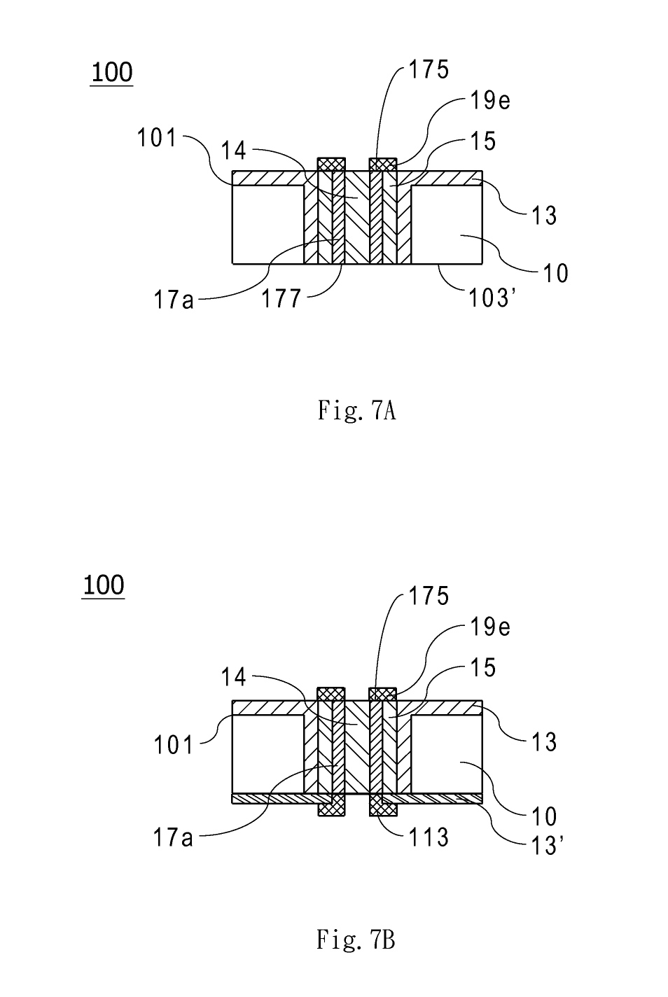

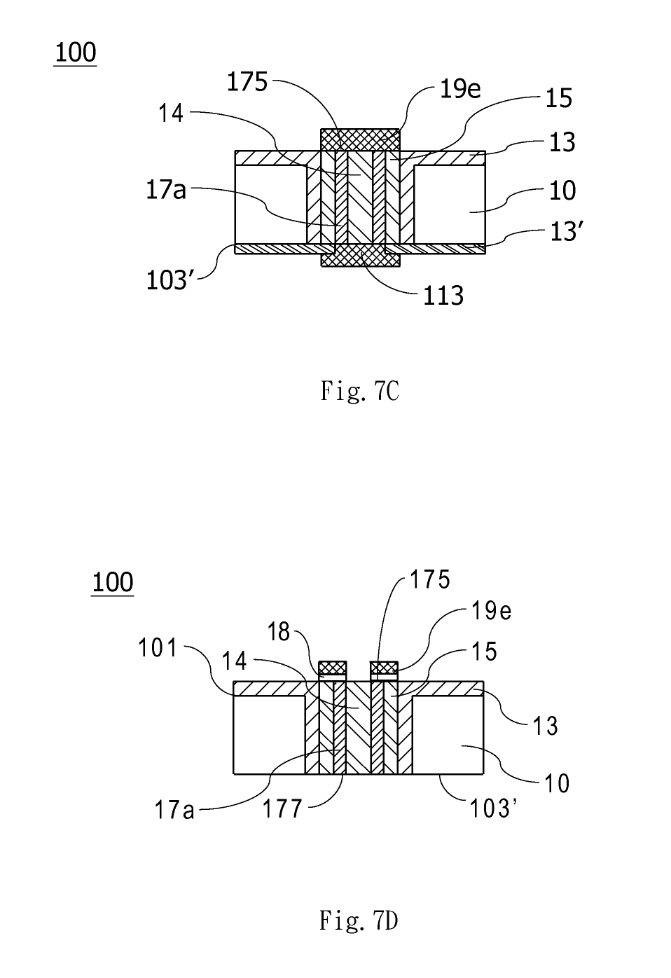

In addition, the present invention provides another embodiment as shown in FIG. 7A to FIG. 7C. First, referring to FIG. 7A, a polymer dielectric material is filled into the hollow region 12 to form a polymer insulating layer 14 therein after the structure of FIG. 5A is fabricated. Then, a soft metal cap 19e is formed on the first end 175 of the ringlike filling metal layer 17a to be a metal electrode structure. Next, the semiconductor wafer 10 is thinned on the second surface 103 until the second end 177 of the ringlike filling metal layer 17a is exposed, and a soft metal cap 113 is then formed on the exposed second end 177 of the ringlike filling metal layer 17a to be a metal electrode structure, as shown in FIG. 7B. In this embodiment, the hollow region 12 is filled with a polymer insulating layer 14 to prevent excessive gases or liquids from getting into the hollow region 12 which may lead to formation of void in the ringlike filling metal layer 17a. Meanwhile, the polymer insulating layer 14 also can serve as a stress buffer. The structure of the soft metal cap 19e and the soft metal cap 113 is not limited to the ringlike structure, but can also be a solid structure, as shown in FIG. 7C. Similarly, the size and the type of the soft metal caps 19e and 113 as described above can be adjusted according to the requirements. The material of the polymer insulating layer 14 can be selected from polyimide, BCB (Benzocyclobutene) or the like.

Furthermore, the present invention discloses an embodiment of through-silicon-via electrode structures, as shown in FIG. 7D. After the ringlike filling metal layer 17a is formed and the polymer insulating layer 14 is filled in the vacancy 12 as shown in FIG. 7A, a UBM layer 18 is formed on the first end 175 of the ring-like filling metal layer 17a by evaporation, sputtering, electroplating, or electroless plating method. The UBM layer 18 may also be formed on the polymer insulating layer 14 and on the first surface 101 of the semiconductor wafer 10, overlaying the barrier layer 15 and even a portion of the dielectric layer 13. The soft metal cap 19e is then formed on the UBM layer 18 as an electrode structure. The UBM layer 18 formed on the polymer insulating layer 14 and on the first surface 101 of the semiconductor wafer 10 can be removed optionally by, for example, wet etching method so that only the part of UBM layer 18 interposed between the first end 175 of the ringlike filling metal layer 17a and the soft metal cap 19e remains, as shown in FIG. 7D. Apparently, forming a UBM layer can also be applied to the structures as shown in FIGS. 7B and 7C in a similar way, where a UBM layer can also be formed between the second end 177 of the ringlike filling metal layer 17a and the soft metal cap 113. The thickness, material and function of the UBM layers are the same as that shown in FIG. 1J; thus, detailed description is omitted herein.

Filling the hollow region of the ringlike filling metal layer with the polymer insulating layer can further release additional stresses induced by CTE mismatch and to prevent excessive gases or liquids getting into the hollow region for chip stacking of the multi-chip stack structures. It can compensate horizontal deformations which may occur at the interface between two bonded metal electrodes due to the CTE mismatch, and function as a stress buffer, which leads to an increase of reliability for forming the multi-chip stack structures.

Now, through-silicon-via electrode structures with soft metal caps formed on one or both ends of each of the through-silicon holes are formed in each of the plurality of chip areas 100 corresponding to a plurality of pads disposed on the semiconductor wafer 10, wherein the soft metal caps serve as the contacts for external electrical connection. Then, chip stacking process can be performed. After an alignment process is performed, a semiconductor chip with a plurality of through-silicon-via electrode structures and another semiconductor chip with a plurality of through-silicon-via electrode structures are vertically stacked on and bonded to each other by thermo-compressing process, thermo-sonic bonding process, or ultrasonic bonding process such that the second ends of the ringlike filling metal layers or the soft metal caps protruding out of the second surface of an upper chip are connected with the soft metal caps protruding out of the first surface of a lower chip, respectively. In the present invention, ultrasonic bonding is the most preferred bonding method. Accordingly, the foregoing two-chip stack structure can further be vertically bonded to more semiconductor chips similarly configured with a plurality of through-silicon-via electrode structures to form a three-dimensional multi-chip stack structure. Furthermore, it should be explained that process for forming the multi-chip stack structures can be preformed by stacking a plurality of semiconductor wafers 10 to form a wafer-to-wafer stack structure, followed by a wafer saw process which is performed to cut along the scribe lines between the plurality of chip areas on the semiconductor wafers 10 of the stacked wafer structure to form a plurality of multi-chip stack structures. Alternatively, the semiconductor wafer 10 can first be sawed into a plurality of individual semiconductor chips. Then, the plurality of individual semiconductor chips are stacked to one another to form a chip-to-chip multi-chip stack structure. Also, the plurality of individual semiconductor chips can be bonded to the chip areas of the semiconductor wafer 10 correspondingly to form a chip-to-wafer stack structure, followed by a wafer saw process performed along the scribe lines between the plurality of chip areas on the semiconductor wafer 10 to form a plurality of multi-chip stack structures. The number of semiconductor chips to be stacked is not to be limited in this invention.

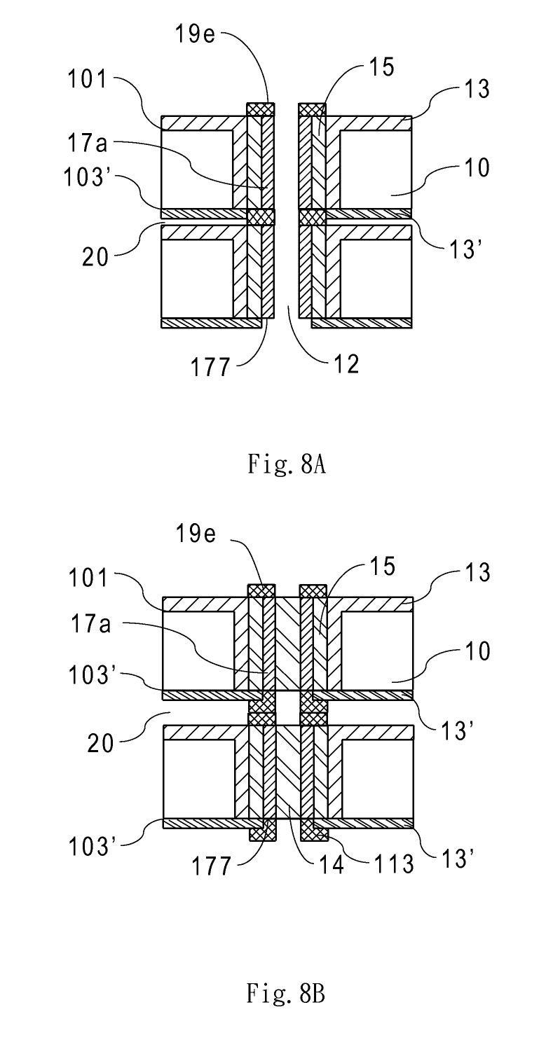

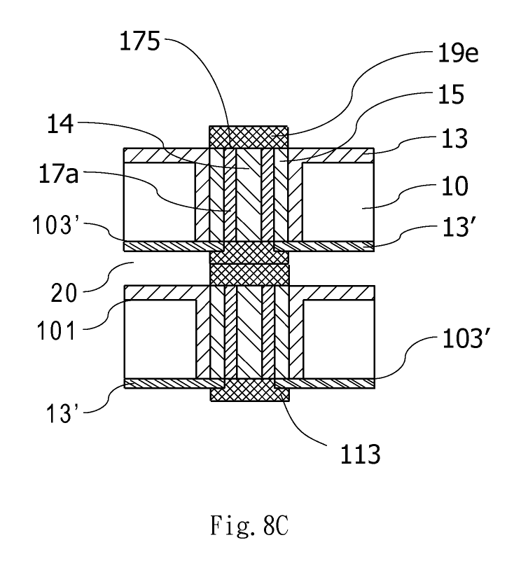

The first embodiment of multi-chip stack structure with ringlike filling metal layers, as shown in FIG. 8A, is formed by vertically stacking a plurality of semiconductor chips with through-silicon-via electrode structures of FIG. 6A. Please also refer to the FIG. 1A to FIG. 1C. For the multi-chip stack structure of this embodiment, each of the plurality of semiconductor chips has a first 101 and a second surface 103′ opposite the first surface 101, and a plurality of through-silicon holes formed therein. The plurality of through-silicon holes connect the first surface 101 and the second surface 103′ of the semiconductor chip, and a through-silicon-via electrode structure is formed in each of the plurality of through-silicon holes. The through-silicon-via electrode structure comprises a dielectric layer 13 formed on an inner wall of the through-silicon hole, a barrier layer 15 formed on an inner wall of the dielectric layer 13 and defining a vacancy 11a, a ringlike filling metal layer 17a formed on an inner wall of the barrier layer 15 and partially filling the vacancy 11a to form a hollow region 12 therein, wherein the first end 175 of the ringlike filling metal layer 17a is flush with the first surface 101 and the second end 177 is flush with the second surface 103′, and a soft metal cap 19e formed on the first end 175 of the ringlike filling metal layer 17a and protruding from the first surface 101. Thus, in this embodiment, the multi-chip stack structure is formed by connecting a plurality of soft metal cap 19e of one of the plurality of semiconductor chips to the second ends 177 of the plurality of ringlike filling metal layers 17a of another semiconductor chip.

Then, the present invention provides a second embodiment of multi-chip stack structure with ringlike filling metal layer, as shown in FIG. 8B, which is formed by vertically stacking a plurality of semiconductor chips with through-silicon-via electrode structures of FIG. 7B. Apparently, the difference between this embodiment and the embodiment in FIG. 8A is that a polymer dielectric material is filled in the hollow region 12 to form a polymer insulating layer 14, and a soft metal cap 113 is further formed on the second end 177 of the ringlike filling metal layer 17a as shown in FIG. 7B. Thus, the multi-chip stack structure is formed by connecting the plurality of soft metal caps 19e of one of the plurality of semiconductor chips to the plurality of soft metal caps 113 of another semiconductor chip, as shown in FIG. 8B.

Next, the present invention provides a third embodiment of the multi-chip stack structure with ringlike filling metal layer, as shown in FIG. 8C, which is formed by vertically stacking a plurality of semiconductor chips with through-silicon-via electrode structures of FIG. 7C. The difference between this embodiment and the embodiment in FIG. 8B is that the soft metal caps 19e and 113 are solid structures in FIG. 8C. Here, the multi-chip stack structure of FIG. 8C is formed by connecting the plurality of soft metal caps 19e of one of the plurality of semiconductor chips to the plurality of soft metal caps 113 of another semiconductor chip.

It should be emphasized that the above-mentioned constitutions of the multi-chip stack structures are only some embodiments of the present invention. Any combinations of semiconductor chips with the through-silicon-via electrode structures as disclosed in FIG. 6A, FIG. 6B, FIG. 6D, FIG. 7A, FIG. 7B, or FIG. 7C can be selected for fabricating the multi-chip stack structures. Thus, the present invention is not limit to the foregoing embodiments in FIG. 8A to FIG. 8C.

Meanwhile, a sealing application also can be optionally performed during the multi-chip stacking process. A sealing material can be applied on the first surface 101 of the semiconductor wafer 10 or chip by dispensing, printing, or spin-coating method. When the semiconductor wafers or chips are bonded together, the sealing material is cured to form a sealing layer 28 in the gap 20 between each two adjacent semiconductor wafers or chips of the multi-chip stack structures, as shown in FIG. 9. Thus, the sealing layer 28 can facilitate the multi-chip stack structure to be securely bonded and protect the electrical interconnects. The material of the sealing layer 28 is selected from the group consisting of: non-conductive paste (NCP), non-conductive film (NCF), anisotropic conductive paste (ACP), anisotropic conductive film (ACF), underfill, non-flow underfill, B-stage resin, molding compound, and film-over-wire (FOW). In the present invention, non-conductive paste (NCP) is the most preferred sealing material. In addition, the sealing application can also be optionally performed after the multi-chip stack structure is fabricated. The sealing material is filled into the gap 20 between each two adjacent semiconductor wafers or chips of the multi-chip stack structures to form the sealing layer 28, as shown in FIG. 9.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

What is claimed is:

1. A semiconductor wafer structure having a first surface and a second surface opposite to said first surface, said first surface having a plurality of chip areas formed thereon, each of said plurality of chip areas having a plurality of through-silicon holes formed therein, said plurality of through-silicon holes connecting said first surface and said second surface, a through-silicon-via electrode structure being formed in each of said plurality of through-silicon holes, said through-silicon-via electrode structure comprising:
a dielectric layer formed on an inner wall of each of said plurality of through-silicon holes;
a barrier layer formed on an inner wall of said dielectric layer and defining a vacancy therein;
a filling metal layer filled into said vacancy, said filling metal layer having a first end and an opposite second end, said first end being lower than said first surface forming a recess therein and said second end being near said second surface; and
a first soft metal cap connected to and overlaying said first end of said filling metal layer, a portion of said first soft metal cap being formed in said recess and said first soft metal cap protruding out of said first surface.

2. The semiconductor wafer structure according to claim 1, wherein said second end of said filling metal layer is flush with said second surface.

3. The semiconductor wafer structure according to claim 2, wherein said through-silicon-via electrode structure further comprises a second soft metal cap, said second soft metal cap being connected to and overlaying said second end of said filling metal layer and protruding out of said second surface.

4. The semiconductor wafer structure according to claim 3, wherein said first soft metal cap and said second soft metal cap are selected from the group consisting of: electroplated bumps, electroless bumps, stud bumps and conductive polymer bumps.

5. The semiconductor wafer structure according to claim 4, wherein the material of said first soft metal cap and said second soft metal cap is selected from the group consisting of: gold, nickel/gold, nickel/palladium/gold, tin solder, lead-free solder, and conductive polymer material.

6. The semiconductor wafer structure according to claim 1, wherein the material of said filling metal layer is selected from the group consisting of: poly-silicon, copper, tungsten, nickel, aluminum, and the combination thereof.

7. The semiconductor wafer structure according to claim 1, further comprising an UBM layer formed between said first end of said filling metal layer and said first soft metal cap.

8. The semiconductor wafer structure according to claim 3, further comprising an UBM layer formed between said second end of said filling metal layer and said second soft metal cap.

9. A semiconductor wafer structure having a first surface and a second surface opposite to said first surface, said first surface having a plurality of chip areas formed thereon, each of said plurality of chip areas having a plurality of through-silicon holes formed therein, said plurality of through-silicon holes connecting said first surface and said second surface, a through-silicon-via electrode structure being formed in each of said plurality of through-silicon holes, said through-silicon-via electrode structure comprising:
a dielectric layer formed on an inner wall of each of said plurality of through-silicon holes;
a barrier layer formed on an inner wall of said dielectric layer and defining a vacancy therein;
a filling metal layer filled into said vacancy, said filling metal layer having a first end and an opposite second end, said first end being lower than said first surface forming a first recess therein and said second end being lower than said second surface forming a second recess therein; and
a first soft metal cap connected to and overlaying said first end of said filling metal layer, a portion of said first soft metal cap being formed in said first recess and said first soft metal cap protruding out of said first surface.

10. The semiconductor wafer structure according to claim 9, wherein said through-silicon-via electrode structure further comprises a second soft metal cap, said second soft metal cap being connected to and overlaying said second end of said filling metal layer, a portion of said second soft metal cap being formed in said second recess and said second soft metal cap protruding out of said second surface.

11. The semiconductor wafer structure according to claim 10, wherein said first soft metal cap and said second soft metal cap are selected from the group consisting of: electroplated bumps, electroless bumps, stud bumps and conductive polymer bumps.

12. The semiconductor wafer structure according to claim 11, wherein the material of said first soft metal cap and said second soft metal cap is selected from the group consisting of: gold, nickel/gold, nickel/palladium/gold, tin solder, lead-free solder, and conductive polymer material.

13. The semiconductor wafer structure according to claim 9, wherein the material of said filling metal layer is selected from the group consisting of: poly-silicon, copper, tungsten, nickel, aluminum, and the combination thereof.

14. The semiconductor wafer structure according to claim 9, further comprising an UBM layer formed between said first end of said filling metal layer and said first soft metal cap.

15. The semiconductor wafer structure according to claim 10, further comprising an UBM layer formed between said second end of said filling metal layer and said second soft metal cap.

16. A multi-chip stack structure formed by vertically stacking a plurality of semiconductor chips, each of said plurality of semiconductor chips having a first surface, a second surface opposite to said first surface and a plurality of through-silicon holes formed therein, said plurality of through-silicon holes connecting said first surface and said second surface, a through-silicon-via electrode structure being formed in each of said plurality of through-silicon holes, said through-silicon-via electrode structure comprising:
a dielectric layer formed on an inner wall of each of said through-silicon holes;
a barrier layer formed on an inner wall of said dielectric layer and defining a vacancy therein;
a filling metal layer filled into said vacancy, said filling metal layer having a first end and an opposite second end, said first end being lower than said first surface forming a recess therein and said second end being flush with said second surface; and
a first soft metal cap connected to and overlaying said first end of said filling metal layer, a portion of said first soft metal cap being formed in said recess and said first soft metal cap protruding out of said first surface;
wherein said first soft metal caps of one of said plurality of semiconductor chips are electrically connected to said second ends of said filling metal layers of another one of said plurality of semiconductor chips to form a multi-chip stack structure.

17. The stack structure according to claim 16, wherein said through-silicon-via electrode structure further comprises a second soft metal cap, said second soft metal cap being connected to and overlaying said second end of said filling metal layer and protruding out of said second surface, said first soft metal caps of one of said plurality of semiconductor chips being electrically connected to said second soft metal caps of another one of said plurality of semiconductor chips to form a multi-chip stack structure.

18. The stack structure according to claim 17, wherein said first soft metal cap and said second soft metal cap are selected from the group consisting of: electroplated bumps, electroless bumps, stud bumps and conductive polymer bumps.

19. The stack structure according to claim 18, wherein the material of said first soft metal cap and said second soft metal cap is selected from the group consisting of: gold, nickel/gold, nickel/palladium/gold, tin solder, lead-free solder, and conductive polymer material.

20. The stack structure according to claim 16, wherein the material of said filling metal layer is selected from the group consisting of: poly-silicon, copper, tungsten, nickel, aluminum, and the combination thereof.

21. A multi-chip stack structure formed by vertically stacking a plurality of semiconductor chips, each of said plurality of semiconductor chips having a first surface, a second surface opposite to said first surface and a plurality of through-silicon holes formed therein, said plurality of through-silicon holes connecting said first surface and said second surface, a through-silicon-via electrode structure being formed in each of said plurality of through-silicon holes, said through-silicon-via electrode structure comprising:
a dielectric layer formed on an inner wall of each of said through-silicon holes;
a barrier layer formed on an inner wall of said dielectric layer and defining a vacancy therein;
a filling metal layer filled into said vacancy, said filling metal layer having a first end and an opposite second end, said first end being lower than said first surface forming a first recess therein and said second end being lower than said second surface forming a second recess therein;
a first soft metal cap connected to and overlaying said first end of said filling metal layer, a portion of said first soft metal cap being formed in said first recess and said first soft metal cap protruding out of said first surface; and
a second soft metal cap connected to and overlaying said second end of said filling metal layer, a portion of said second soft metal cap being formed in said second recess and said second soft metal cap protruding out of said second surface;
wherein said first soft metal caps of one of said plurality of semiconductor chips are electrically connected to said second soft metal caps of another one of said plurality of semiconductor chips to form a multi-chip stack structure.

22. The stack structure according to claim 21, wherein the material of said filling metal layer is selected from the group consisting of: poly-silicon, copper, tungsten, nickel, aluminum, and the combination thereof.

23. The stack structure according to claim 21, wherein said first soft metal cap and said second soft metal cap are selected from the group consisting of: electroplated bumps, electroless bumps, stud bumps and conductive polymer bumps.

24. The stack structure according to claim 23, wherein the material of said first soft metal cap and said second soft metal cap is selected from the group consisting of: gold, nickel/gold, nickel/palladium/gold, tin solder, lead-free solder, and conductive polymer material.
